(19) United States
(12) Patent Application Publication
(10) Pub. No.: US 2017/0310367 A1
(43) Pub. Date: Oct. 26, 2017

(54) ELECTRONIC DEVICE FOR TRANSMITTING ELECTROMAGNETIC WAVE IN MULTIPLE DIRECTIONS

(71) Applicant: Samsung Electronics Co., Ltd., Gyeonggi-do (KR)

(72) Inventors: Se Hwan CHOI, Gyeonggi-do (KR); Jung Sik PARK, Gyeonggi-do (KR); Woo Sup LEE, Gyeonggi-do (KR); Geon Woo KIM, Gyeonggi-do (KR)

(73) Assignee: Samsung Electronics Co., Ltd.

(21) Appl. No.: 15/497,846

(22) Filed: Apr. 26, 2017

(30) Foreign Application Priority Data
Apr. 26, 2016 (KR) 10-2016-0050891

(51) Int. Cl. H04B 5/00; H05K 1/02; H04W 4/00; H01L 25/065; G06F 1/16; H01L 23/58; H01L 23/522; H05K 1/16

(52) U.S. Cl. CPC H04B 5/0031; H05K 1/165; H05K 1/028; H04W 4/008; H04B 5/0081; G06F 1/1637; H01L 23/58; H01L 23/5227; G06F 1/1698; H01L 25/0655

(57) ABSTRACT

An electronic device of the present disclosure is provided. The electronic device includes a housing having a first plate facing a first direction, a second plate facing a second direction, and at least one side part, between the first plate and the second plate, facing a third direction, a first conductive pattern comprising a first coil having a first axis substantially extending in the first direction or the second direction, a second conductive pattern comprising a second coil having a second axis substantially extending in the third direction, and a communication circuit connected with the first conductive pattern and the second conductive pattern.

### PRIORITY

This application claims priority under 35 U.S.C. §119(a) to a Korean Patent Application filed on Apr. 26, 2016, in the Korean Intellectual Property Office and assigned Serial No. 10-2016-0050891, the entire disclosure of which is incorporated herein by reference.

### BACKGROUND OF THE DISCLOSURE

### 1. Field of the Disclosure

The present disclosure relates generally to an electronic device that radiates electromagnetic waves by using a conductive pattern.

### 2. Description of the Related Art

With the development of information and communication technology, network devices, such as a base station, are installed throughout the country. An electronic device, such as the base station, transmits and receives data to and from another electronic device over a network, and thus, a user is able to utilize the network freely anywhere in the country.

Various kinds of electronic devices provide a variety of functions consistent with the recent trend of digital convergence. For example, a smartphone supports a call function, as well as functions to connect to the Internet over the network, play music or a video, and capture video and photos by using an image sensor.

Also, the electronic device includes a plurality of antennas to use different kinds of networks.

In a conventional electronic device, a conductive pattern for near field communication (NFC) is mounted in a rear case or a battery of the electronic device. Since electromagnetic waves of the NFC travels in straight lines and has a short effective distance, communication may be possible only when the NFC conductive pattern is close to an NFC reader. However, it is difficult for a user to be fully aware of a location of the NFC conductive pattern mounted inside the electronic device.

### SUMMARY

The present disclosure has been made to address at least the above-mentioned problems and/or disadvantages and to provide at least the advantages described below.

Accordingly, an aspect of the present disclosure is to perform wireless communication in a plurality of directions by using conductive patterns provided at different locations of an electronic device.

Accordingly, another aspect of the present disclosure is to perform wireless communication in a plurality of directions by using a plurality of conductive patterns (e.g., an NFC coil, an MST coil, etc.) in an electronic device, thereby preventing communication failure occurring when a user does not exactly perceive a location of a wireless communication conductive pattern.

In accordance with an aspect of the present disclosure, an electronic device is provided. The electronic device includes a housing having a first plate facing a first direction, a second plate facing a second direction, and at least one side part, between the first plate and the second plate, facing a third direction, a first conductive pattern comprising a first coil having a first axis substantially extending in the first direction or the second direction, a second conductive pattern comprising a second coil having a second axis substantially extending in the third direction, and a communication circuit connected with the first conductive pattern and the second conductive pattern.

In accordance with another aspect of the present disclosure, an electronic device is provided. The electronic device includes a main display facing in a first direction, a housing equipped with the main display, a first conductive pattern and a second conductive pattern disposed inside the housing, and a communication circuit configured to transmit and receive wireless electromagnetic waves to and from an outside of the electronic device, through the first conductive pattern and the second conductive pattern. The first conductive pattern generates wireless electromagnetic waves in the first direction or a second direction, and the second conductive pattern generates wireless electromagnetic waves in a third direction.

In accordance with another aspect of the present disclosure, an electronic device includes a first conductive pattern outputting electromagnetic waves in a first direction, a second conductive pattern outputting electromagnetic waves in a second direction forming a specified angle with the first direction, and a communication circuit connected with the first conductive pattern and the second conductive pattern. The communication circuit performs short range communication with an external device by using at least one of the first conductive pattern and the second conductive pattern.

### BRIEF DESCRIPTION OF THE DRAWINGS

The above and other aspects, features, and advantages of embodiments of the present disclosure will be more apparent from the following description taken in conjunction with the accompanying drawings, in which:

FIG. 1 is a block diagram of an electronic device in a network environment, according to an embodiment of the present disclosure;

FIG. 2 is a block diagram of a configuration of an electronic device, according to an embodiment of the present disclosure;

FIG. 3 is a block diagram of a configuration of a program module of an electronic device, according to an embodiment of the present disclosure;

FIG. 4A is illustrates the outside of an electronic device including a plurality of conductive patterns, according to an embodiment of the present disclosure;

FIGS. 4B and 4C illustrate an inside of the electronic device including a plurality of conductive patterns, according to an embodiment of the present disclosure;

FIGS. 5A and 5B illustrate a plurality of conductive patterns mounted in an electronic device, according to an embodiment of the present disclosure;

FIG. 6A illustrates a configuration of a plurality of conductive patterns that perform short range communication in an electronic device, according to an embodiment of the present disclosure;

FIG. 6B is a block diagram of a communication circuit and a plurality of conductive patterns in an electronic device, according to an embodiment of the present disclosure;

FIG. 7 illustrates a configuration of a plurality of conductive patterns that perform short range communication in an electronic device, according to an embodiment of the present disclosure;

FIG. 8A is a block diagram of a communication circuit and a plurality of conductive patterns in an electronic device, according to an embodiment of the present disclosure;

FIG. 8B is a flowchart of a method for performing communication by using a differential signal in an electronic device, according to an embodiment of the present disclosure;

FIGS. 9A and 9B illustrate an electromagnetic wave transmission path that is based on a wound direction of a coil and a location of a non-conductor, according to an embodiment of the present disclosure;

FIGS. 10A and 10B illustrate a configuration of a plurality of conductive patterns in an electronic device having a display covering multiple surfaces, according to an embodiment of the present disclosure;

FIG. 11 illustrates a configuration of a plurality of conductive patterns in an electronic device having a display covering multiple surfaces, according to an embodiment of the present disclosure;

FIGS. 12A to 12D illustrate a configuration of a plurality of conductive patterns in an electronic device having a flexible display, according to an embodiment of the present disclosure; and

FIG. 13 illustrates a configuration of a plurality of conductive patterns in a wearable electronic device, according to an embodiment of the present disclosure.

### DETAILED DESCRIPTION OF EMBODIMENTS OF THE PRESENT DISCLOSURE

Various embodiments of the present disclosure will be described with reference to the accompanying drawings in which similar components may be marked by similar reference numerals. However, the present disclosure is not intended to be limited by the embodiments described herein. Accordingly, those of ordinary skill in the art will recognize that modifications, equivalents, and/or alternatives of the various embodiments described herein can be made without departing from the spirit and the scope of the present disclosure. The expressions “have”, “include” and “comprise”, used herein, refer to the existence of corresponding features (for example, numeric values, functions, operations, or components) but do not exclude the presence of additional features.

The expressions “A or B”, “at least one of A or/and B”, and “one or more of A or/and B”, used herein, may include any and all combinations of one or more of the associated listed items. For example, the expressions “A or B”, “at least one of A and B”, and “at least one of A or B” may refer to (1) A (2) B or (3) A and B.

The terms “first”, “second”, etc., used herein, may refer to various elements regardless of the order or the importance, but do not limit the elements. For example, such terms may be used to distinguish an element from another element and do not limit the order and/or priority of the elements. For example, a “first user device” and a “second user device” may represent different user devices irrespective of sequence or importance. For example, without departing from the scope of the present disclosure, a first element may be referred to as a second element, and similarly, a second element may be referred to as a first element.

It should be understood that when an element (for example, a first element) is referred to as being “coupled” or “connected” with/to another element (for example, a second element), it can be directly coupled or connected with/to the other element or an intervening element (for example, a third element) may be present. In contrast, when an element (for example, a first element) is referred to as being “directly coupled” or “directly connected” with/to another element (for example, a second element), it should be understood that there are no intervening elements (for example, a third element).

The expression “configured to”, used herein, may be used interchangeably with, for example, the expressions “suitable for”, “having the capacity to”, “designed to”, “adapted to”, “made to”, and “capable of”. The expression “configured to (or set to)” does not mean only “specifically designed to” in hardware. Instead, for example, the expression “a device configured to” may mean that the device is “capable of” operating together with another device or other components. For example, a “processor configured to (or set to) perform A, B, and C” may refer to a dedicated processor (for example, an embedded processor) for performing a corresponding operation or a generic-purpose processor (for example, a central processing unit (CPU) or an application processor (AP)) which may perform corresponding operations by executing one or more software programs which are stored in a memory device.

Terms used in this specification are used to describe specified embodiments of the present disclosure and are not intended to limit the scope of the present disclosure. The terms of a singular form may include plural forms as well, unless otherwise specified. Unless otherwise defined herein, all the terms used herein, which include technical or scientific terms, may have the same meaning as those commonly understood by a person skilled in the art to which the present disclosure pertains. It should be further understood that terms, which are defined in a generally used dictionary, should be interpreted as is customary in the relevant related art and not in an idealized or overly formal manner, unless expressly so defined herein. In some cases, even if terms are defined herein, they should not be interpreted to exclude embodiments of the present disclosure.

An electronic device according to an embodiment of the present disclosure may include at least one of a smart phone, a tablet personal computer (PC), a mobile phone, a video telephone, an electronic book reader, a desktop PC, a laptop PC, a netbook computer, a workstation, a server, a personal digital assistants (PDA), a portable multimedia player (PMP), an MP3 player, a mobile medical device, a camera, and a wearable device. The wearable device may include an accessory (for example, a watch, a ring, a bracelet, an ankle bracelet, glasses, contact lenses, or a head-mounted device (HMD)), a cloth-integrated type (for example, electronic clothes), a body-attached type (for example, a skin pad or tattoo), or an implantable type (for example, an implantable circuit).

In some embodiments of the present disclosure, the electronic device may be a home appliance. The home appliance may include at least one of a digital versatile disk (DVD) player, an audio device, a refrigerator, an air conditioner, a cleaner, an oven, a microwave oven, a washing machine, an air cleaner, a set-top box, a home automation control panel, a security control panel, a TV box (for example, Samsung HomeSync™, Apple TV™, or Google TV™), a game console (for example, Xbox™ or PlayStation™), an electronic dictionary, an electronic key, a camcorder, or an electronic panel.

In another embodiment of the present disclosure, the electronic device may include at least one of a medical device (for example, a portable medical measurement device (e.g., a blood glucose meter, a heart rate measuring device, a blood pressure measuring device, and a body temperature measuring device), a magnetic resonance angiography (MRA) device, a magnetic resonance imaging (MRI) device, a computed tomography (CT) device, a photographing device, and an ultrasonic device), a navigation system, a global navigation satellite system (GNSS), an event data recorder (EDR), a flight data recorder (FDR), a vehicular infotainment device, an electronic device for vessels (for example, a navigation device for vessels and a gyro compass), an avionics device, a security device, a vehicular head unit, a robot, an automatic teller machine (ATM), a point of sales (POS) device, or an Internet of things (IoT) device (for example, a light bulb, a sensor, an electricity or gas meter, a spring cooler device, a fire alarm device, a thermostat, an electric pole, a toaster, a sporting apparatus, a hot water tank, a heater, and a boiler).

According to some embodiments of the present disclosure, the electronic device may include at least one of a furniture or a part of a building/structure, an electronic board, an electronic signature receiving device, a projector, or a measurement device (for example, a water service, electricity, gas, or electric wave measuring device).

According to some embodiments of the present disclosure, the electronic device may be a flexible electronic device.

The electronic device may be one or a combination of the aforementioned devices. Further, the electronic device is not limited to the aforementioned devices, but may include new electronic devices produced due to the development of new technologies.

Hereinafter, electronic devices according to an embodiment of the present disclosure will be described with reference to the accompanying drawings. The term “user”, used herein, may refer to a person who uses an electronic device or may refer to a device (for example, an artificial intelligence electronic device) that uses an electronic device.

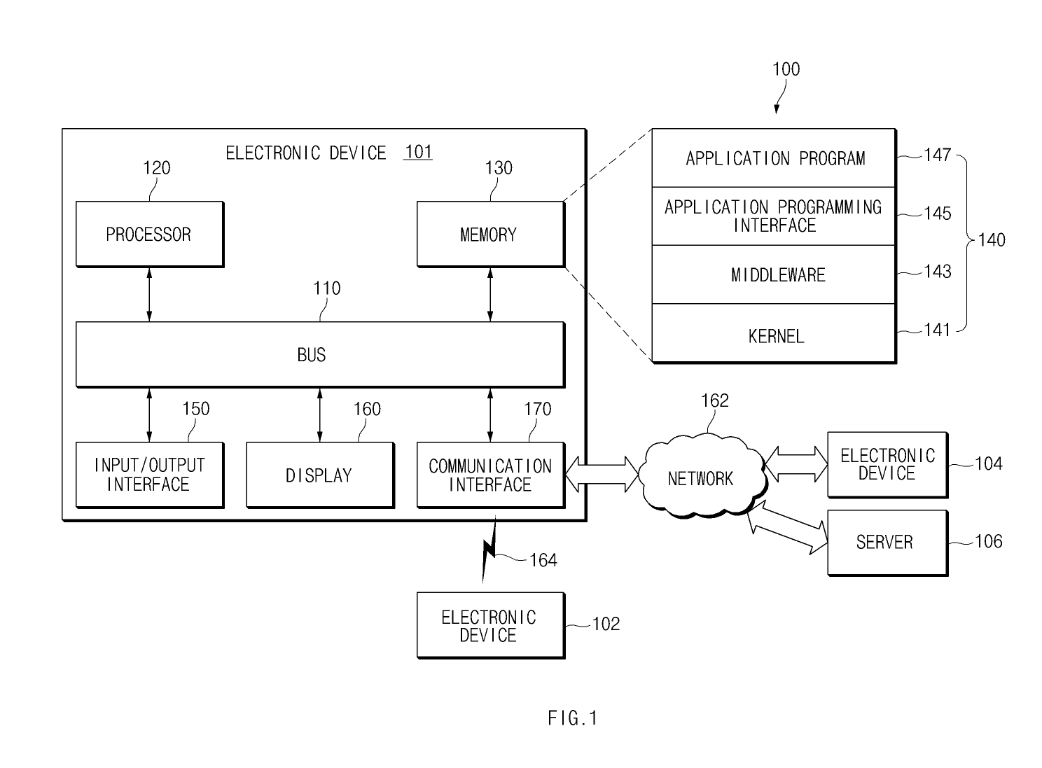

FIG. 1 is a block diagram of an electronic device in a network environment, according to an embodiment of the present disclosure.

Referring to FIG. 1, an electronic device 101 in a network environment 100 is provided. The electronic device 101 includes a bus 110, a processor 120, a memory 130, an input/output interface 150, a display 160, and a communication interface 170. At least one of the foregoing elements may be omitted or another element may be added to the electronic device 101.

The bus 110 is a circuit for connecting the above-mentioned elements 110 to 170 of the electronic device 101 to each other and transferring communications (e.g., control messages and/or data) among the above-mentioned elements.

The processor 120 includes at least one of a CPU, an AP, or a communication processor (CP). The processor 120 may perform data processing or an operation related to communication and/or control of at least one of the other elements of the electronic device 101.

The memory 130 may include a volatile memory and/or a nonvolatile memory. The memory 130 may store instructions or data related to at least one of the other elements of the electronic device 101. The memory 130 may store software and/or a program 140. The program 140 includes a kernel 141, a middleware 143, an application programming interface (API) 145, and/or an application program (or an application) 147. At least a portion of the kernel 141, the middleware 143, or the API 145 may be referred to as an operating system (OS).

The kernel 141 may control or manage system resources (e.g., the bus 110, the processor 120, the memory 130, etc.) used to perform operations or functions of other programs (e.g., the middleware 143, the API 145, or the application 147). Furthermore, the kernel 141 may provide an interface for allowing the middleware 143, the API 145, or the application 147 to access individual elements of the electronic device 101 in order to control or manage the system resources.

The middleware 143 may serve as an intermediary so that the API 145 or the application 147 communicates and exchanges data with the kernel 141.

Furthermore, the middleware 143 may handle one or more task requests received from the application 147 according to a priority order. For example, the middleware 143 may assign at least one application 147 a priority for using the system resources (e.g., the bus 110, the processor 120, the memory 130, etc.) of the electronic device 101. For example, the middleware 143 may handle the one or more task requests according to the priority assigned to the at least one application 147, thereby performing scheduling or load balancing with respect to the one or more task requests.

The API 145, which is an interface for allowing the application 147 to control a function provided by the kernel 141 or the middleware 143, may include at least one interface or function (e.g., instructions) for file control, window control, image processing, character control, etc.

The input/output interface 150 may serve to transfer an instruction or data input from a user or another external device to another element of the electronic device 101. Furthermore, the input/output interface 150 may output instructions or data received from another element of the electronic device 101 to the user or another external device.

The display 160 may include a liquid crystal display (LCD), a light-emitting diode (LED) display, an organic light-emitting diode (OLED) display, a microelectromechanical systems (MEMS) display, or an electronic paper display. The display 160 may present various content (e.g., a text, an image, a video, an icon, a symbol, etc.) to the user. The display 160 may include a touch screen, and may receive a touch, gesture, proximity or hovering input from an electronic pen or a part of a body of the user.

The communication interface 170 may set communication between the electronic device 101 and a first external electronic device 102, a second external electronic device 104, or a server 106. For example, the communication interface 170 may be connected to the first external electronic device 102 through short range communication 164 and may be connected to the second external electronic device 104 and the server 106 through a network 162 via wireless communication or wired communication so as to communicate with the external device.

The wireless communication may employ at least one of cellular communication protocols such as long-term evolution (LTE), LTE-advance (LTE-A), code division multiple access (CDMA), wideband CDMA (WCDMA), universal mobile telecommunications system (UMTS), wireless broadband (WiBro), or global system for mobile communications (GSM). The wireless communication may include the short-range communication 164. The short-range communication 164 may include at least one of Wi-Fi), Bluetooth (BT), Bluetooth low energy (BLE), Zigbee, NFC, magnetic stripe transmission (MST), or GNSS.

The MST may generate pulses according to a transmission of data and the pulses may generate electromagnetic signals. The electronic device 101 may transmit the electromagnetic signals to a reader device such as a POS device. The POS device may detect the magnetic signals by using a MST reader and restore data by converting the detected electromagnetic signals into electrical signals.

The GNSS may include at least one of a global positioning system (GPS), global navigation satellite system (GLONASS), Beidou navigation satellite system (Beidou), or Galileo, the European global satellite-based navigation system according to a use area or a bandwidth. Hereinafter, the term “GPS” and the term “GNSS” may be interchangeably used.

The wired communications may include at least one of a universal serial bus (USB), a high definition multimedia interface (HDMI), a recommended standard 832 (RS-232), a plain old telephone service (POTS), etc.

The network 162 may include at least one of a telecommunications network, for example, a computer network (e.g., local area network (LAN) or wide area network (WAN)), the Internet, or a telephone network.

The first external electronic device 102 and the second external electronic device 104 may be the same as or different from the type of the electronic device 101. The server 106 may include a group of one or more servers. A portion or all of operations performed in the electronic device 101 may be performed in one or more other electronic devices (e.g., the first electronic device 102, the second external electronic device 104, or the server 106). When the electronic device 101 should perform a certain function or service automatically or in response to a request, the electronic device 101 may request at least a portion of functions related to the function or service from another device instead of or in addition to performing the function or service for itself. The other electronic device may perform the requested function or additional function, and may transfer a result of the performance to the electronic device 101. The electronic device 101 may use a received result itself or additionally process the received result to provide the requested function or service. To this end, for example, a cloud computing technology, a distributed computing technology, or a client-server computing technology may be used.

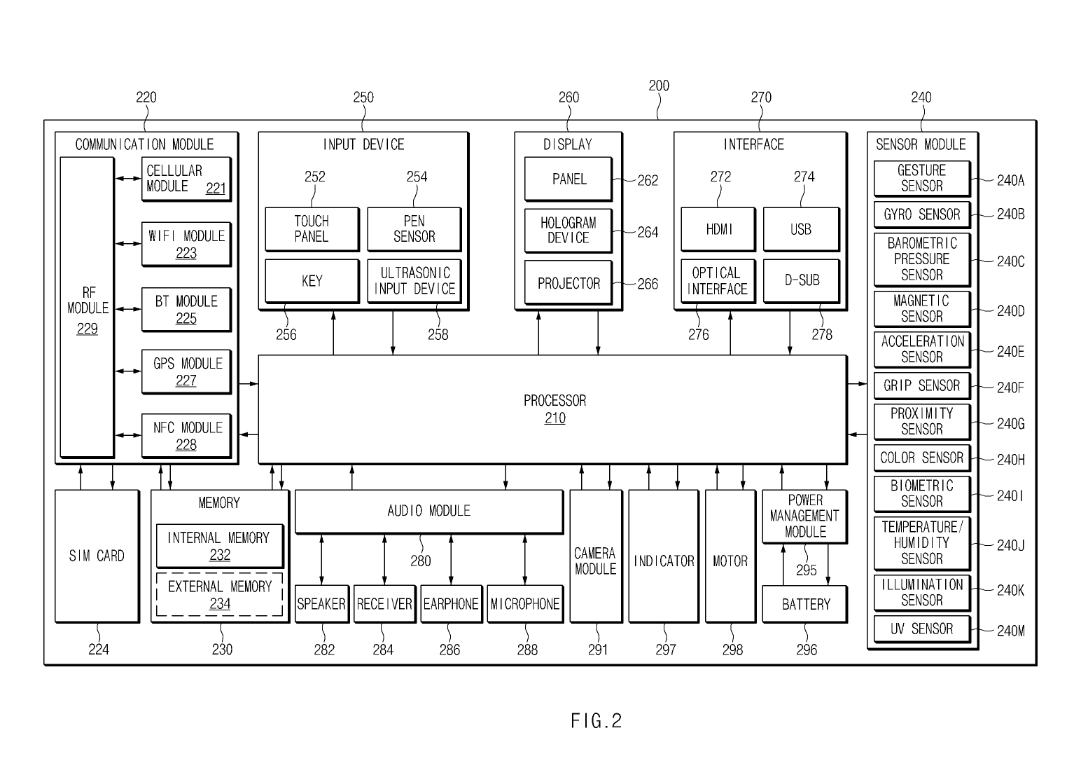

FIG. 2 is a block diagram of a configuration of an electronic device, according to an embodiment of the present disclosure.

Referring to FIG. 2, an electronic device 200 is provided. The electronic device 200 includes at least one processor 210, a communication module 220, a subscriber identification module (SIM) card 224, a memory 230, a sensor module 240, an input device 250, a display 260, an interface 270, an audio module 280, a camera module 291, a power management module 295, a battery 296, an indicator 297, and a motor 298.

The processor 210 may run an OS or an application program so as to control a plurality of hardware or software elements connected to the processor 210, and may process various data and perform operations. The processor 210 may be implemented with a system on chip (SoC). The processor 210 may further include a graphic processing unit (GPU) and/or an image signal processor (ISP). The processor 210 may include at least a portion (e.g., a cellular module 221) of the elements of the electronic device 200. The processor 210 may load, on a volatile memory, an instruction or data received from at least one of other elements (e.g., a nonvolatile memory) to process the instruction or data, and may store various data in a nonvolatile memory.

The communication module 220 includes, for example, the cellular module 221, a Wi-Fi module 223, a BT module 225, a GPS module 227, a NFC module 228, and a radio frequency (RF) module 229.

The cellular module 221 may provide a voice call service, a video call service, a text message service, or an Internet service through a communication network. The cellular module 221 may identify and authenticate the electronic device 200 in the communication network using the SIM card 224. The cellular module 221 may perform at least a part of the functions that may be provided by the processor 210. The cellular module 221 may include a communication processor (CP).

Each of the Wi-Fi module 223, the BT module 225, the GPS module 227, and the NFC module 228 may include a processor for processing data transmitted/received through the modules. According to some various embodiments of the present disclosure, at least a part (e.g., two or more) of the cellular module 221, the Wi-Fi module 223, the Bluetooth module 225, the GPS module 227, and the NFC module 228 may be included in a single integrated chip (IC) or IC package.

The RF module 229 may transmit/receive communication signals (e.g., RF signals). The RF module 229 includes a transceiver, a power amp module (PAM), a frequency filter, a low noise amplifier (LNA), an antenna, etc. At least one of the cellular module 221, the Wi-Fi module 223, the BT module 225, the GPS module 227, or the NFC module 228 may transmit/receive RF signals through a separate RF module.

The SIM card 224 may include an embedded SIM and/or a card containing the SIM, and may further include unique identification information (e.g., an integrated circuit card identifier (ICCID)) or subscriber information (e.g., international mobile subscriber identity (IMSI)).

The memory 230 includes an internal memory 232 or an external memory 234.

The internal memory 232 may include at least one of a volatile memory (e.g., a dynamic RAM (DRAM), a static RAM (SRAM), a synchronous dynamic RAM (SDRAM), or the like), a nonvolatile memory (e.g., a one-time programmable ROM (OTPROM), a programmable ROM (PROM), an erasable and programmable ROM (EPROM), an electrically erasable and programmable ROM (EEPROM), a mask ROM, a flash ROM, a flash memory (e.g., a NAND flash memory or a NOR flash memory)), a hard drive, or a solid state drive (SSD).

The external memory 234 may include a flash drive, such as a compact flash (CF), a secure digital (SD), a micro-SD, a mini-SD, an extreme digital (xD), a multi-media card (MMC), a memory stick, etc. The external memory 234 may be operatively and/or physically connected to the electronic device 200 through various interfaces.

The sensor module 240 may measure a physical quantity or detect an operational state of the electronic device 200 so as to convert the measured or detected information into an electrical signal. The sensor module 240 may include at least one of a gesture sensor 240A, a gyro sensor 240B, a barometric pressure sensor 240C, a magnetic sensor 240D, an acceleration sensor 240E, a grip sensor 240F, a proximity sensor 240G, a red/green/blue (RGB) sensor 240H, a biometric sensor 240I, a temperature/humidity sensor 240J, an illumination sensor 240K, or an ultraviolet (UV) sensor 240M. Additionally or alternatively, the sensor module 240 may include an olfactory (e-nose) sensor, an electromyography (EMG) sensor, an electroencephalogram (EEG) sensor, an electrocardiogram (ECG) sensor, an infrared (IR) sensor, an iris recognition sensor, and/or a fingerprint sensor. The sensor module 240 may further include a control circuit for controlling at least one sensor included therein. The electronic device 200 may further include a processor configured to control the sensor module 240 as a part of the processor 210 or separately, so that the sensor module 240 is controlled while the processor 210 is in a sleep state.

The input device 250 includes a touch panel 252, a (digital) pen sensor 254, a key 256, or an ultrasonic input device 258.

The touch panel 252 may employ at least one of capacitive, resistive, infrared, and ultraviolet sensing methods. The touch panel 252 may further include a control circuit. The touch panel 252 may further include a tactile layer so as to provide a haptic feedback to a user.

The (digital) pen sensor 254 may include a sheet for recognition which is a part of a touch panel or is separate.

The key 256 may include a physical button, an optical button, or a keypad.

The ultrasonic input device 258 may sense ultrasonic waves generated by an input tool through a microphone 288 so as to identify data corresponding to the ultrasonic waves sensed.

The display 260 includes a panel 262, a hologram device 264, or a projector 266.

The panel 262 may be flexible, transparent, or wearable. The panel 262 and the touch panel 252 may be integrated into a single module.

The hologram device 264 may display a stereoscopic image in the air using an interference of light interference.

The projector 266 may project light onto a screen so as to display an image. The screen may be disposed on the inside or the outside of the electronic device 200.

The display 260 may further include a control circuit for controlling the panel 262, the hologram device 264, or the projector 266.

The interface 270 includes an HDMI 272, a USB 274, an optical interface 276, or a D-subminiature (D-sub) 278. Additionally or alternatively, the interface 270 may include a mobile high-definition link (MHL) interface, an SD card/multi-media card (MMC) interface, or an infrared data association (IrDA) interface.

The audio module 280 may convert a sound into an electrical signal or vice versa. The audio module 280 may process sound information input or output through a speaker 282, a receiver 284, an earphone 286, or the microphone 288.

The camera module 291 is a device for shooting a still image or a video. The camera module 291 may include at least one image sensor (e.g., a front sensor or a rear sensor), a lens, an image signal processor (ISP), or a flash (e.g., an LED or a xenon lamp).

The power management module 295 may manage power of the electronic device 200. The power management module 295 may include a power management integrated circuit (PMIC), a charger integrated circuit (IC), or a battery gauge. The PMIC may employ a wired and/or wireless charging method. The wireless charging method may include a magnetic resonance method, a magnetic induction method, an electromagnetic method, etc. An additional circuit for wireless charging, such as a coil loop, a resonant circuit, a rectifier, etc., may be further included. The battery gauge may measure a remaining capacity, a voltage, current, or temperature of the battery 296.

The battery 296 may include a rechargeable battery and/or a solar battery.

The indicator 297 may display a specific state of the electronic device 200 or a part thereof (e.g., the processor 210), such as a booting state, a message state, a charging state, etc.

The motor 298 may convert an electrical signal into a mechanical vibration, and may generate a vibration or haptic effect.

A processing device (e.g., a GPU) for supporting a mobile TV may be included in the electronic device 200. The processing device for supporting a mobile TV may process media data according to the standards of digital multimedia broadcasting (DMB), digital video broadcasting (DVB), MediaFLO™, etc.

Each of the elements described herein may be configured with one or more components, and the names of the elements may be changed according to the type of an electronic device.

The electronic device may include at least one of the elements described herein, and some elements may be omitted or other additional elements may be added. Furthermore, some of the elements of the electronic device may be combined with each other so as to form one entity, so that the functions of the elements may be performed in the same manner as before the combination.

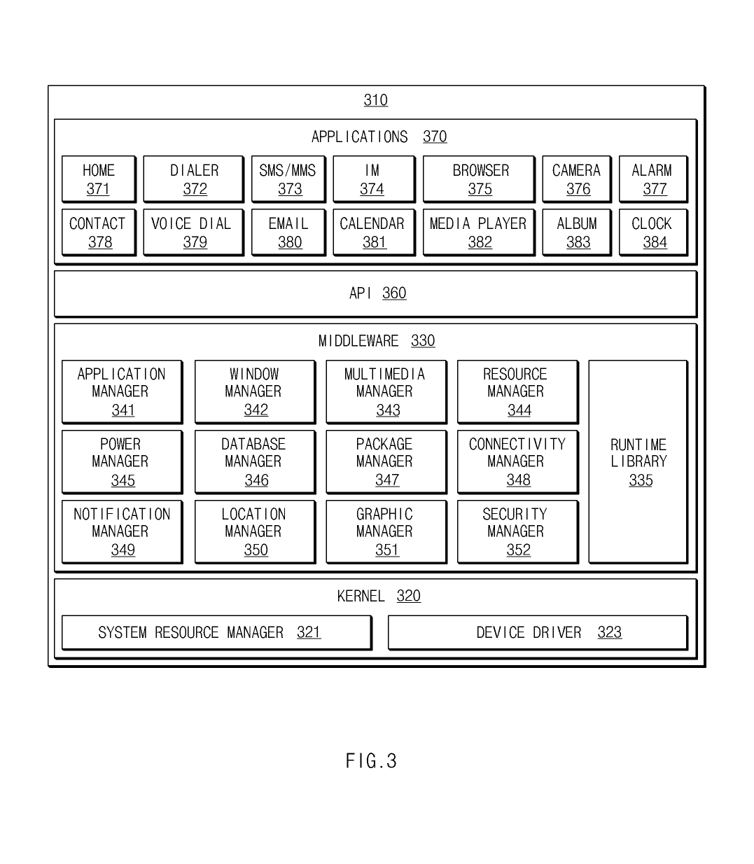

FIG. 3 is a block diagram of a configuration of a program module of an electronic device, according to an embodiment of the present disclosure.

Referring to FIG. 3, a program module 310 is provided. The program module 310 includes an OS for controlling a resource related to the electronic device 101 and/or, the application program 147 running on the OS. The OS may be Android™, iOS™ Windows™, Symbian™, Tizen™, etc.

The program module 310 includes a kernel 320, a middleware 330, an API 360, and/or an applications 370. At least a part of the program module 310 may be preloaded on the electronic device 101 or may be downloaded from the first electronic device 102, the second external electronic device 104, or the server 106.

The kernel 320 includes a system resource manager 321 and a device driver 323. The system resource manager 321 may perform control, allocation, or retrieval of a system resource. The system resource manager 321 may include a process management unit, a memory management unit, a file system management unit, etc. The device driver 323 may include a display driver, a camera driver, a BT driver, a shared memory driver, a USB driver, a keypad driver, a Wi-Fi driver, an audio driver, or an inter-process communication (IPC) driver.

The middleware 330 may provide a function that the applications 370 require in common, or may provide various functions to the applications 370 through the API 360 so that the applications 370 may efficiently use limited system resources in the electronic device 101. The middleware 330 includes at least one of a runtime library 335, an application manager 341, a window manager 342, a multimedia manager 343, a resource manager 344, a power manager 345, a database manager 346, a package manager 347, a connectivity manager 348, a notification manager 349, a location manager 350, a graphic manager 351, and a security manager 352.

The runtime library 335 includes a library module that a complier uses to add a new function through a programming language while the application 370 is running. The runtime library 335 may perform a function for input/output management, memory management, or an arithmetic function.

The application manager 341 may mange a life cycle of at least one of the applications 370.

The window manager 342 may manage a GUI resource used in a screen.

The multimedia manager 343 may recognize a format required for playing various media files and may encode or decode a media file using a codec matched to the format.

The resource manager 344 may manage a resource such as a source code, a memory, or a storage space of at least one of the applications 370.

The power manager 345 may operate together with a basic input/output system (BIOS) to manage a battery or power and may provide power information required for operating the electronic device 101.

The database manager 346 may generate, search, or modify a database to be used in at least one of the applications 370.

The package manager 347 may manage installation or update of an application distributed in a package file format.

The connectivity manger 348 may manage wireless connection of Wi-Fi, BT, etc.

The notification manager 349 may display or notify of an event, such as message arrival, appointments, and proximity alerts, in such a manner as not to disturb a user.

The location manager 350 may manage location information of the electronic device 101.

The graphic manager 351 may manage a graphic effect to be provided to a user or a user interface of the electronic device 101.

The security manager 352 may provide various security functions required for system security or user authentication.

When the electronic device 101 includes a phone function, the middleware 330 may further include a telephony manager for managing a voice or video call function of the electronic device 101.

The middleware 330 may include a middleware module for forming a combination of various functions of the above-mentioned elements. The middleware 330 may provide a module specialized for each type of an OS to provide differentiated functions. Furthermore, the middleware 330 may delete a part of existing elements or may add new elements dynamically.

The API 360, which is a set of API programming functions, may be provided in different configurations according to an OS. For example, in the case of Android™ or iOS™, one API set may be provided for each platform, and, in the case of Tizen™, at least two API sets may be provided for each platform.

The applications 370 may include at least one application capable of performing a home 371, a dialer 372, an SMS/MMS 373, an instant message (IM) 374, a browser 375, a camera 376, an alarm 377, a contact 378, a voice dial 379, an e-mail 380, a calendar 381, a media player 382, an album 383, and a clock 384 function. The applications 370 may additionally include at least one application that provides a health care function (e.g., measure an exercise amount or blood sugar level) or environmental information (e.g., air pressure, humidity, or temperature information).

The applications 370 may include an information exchange application for supporting information exchange between the electronic device 101 and an external electronic device (e.g., the first electronic device 102 or the second external electronic device 104). The information exchange application includes a notification relay application for relaying specific information to the external electronic device or a device management application for managing the external electronic device.

For example, the notification relay application may have a function for relaying, to the external electronic device, notification information generated in another application (e.g., an SMS/MMS application, an e-mail application, a health care application, an environmental information application, etc.) of the electronic device 101. Furthermore, the notification relay application may receive notification information from the external electronic device and may provide the received notification information to the user.

The device management application may manage (e.g., install, delete, or update) at least one function (e.g., turn-on/turn off of the external electronic device itself (or some elements) or the brightness (or resolution) adjustment of a display) of the external electronic device communicating with the electronic device 101, an application running in the external electronic device, or a service (e.g., a call service, a message service, etc.) provided from the external electronic device.

The applications 370 may include a specified application (e.g., a healthcare application of a mobile medical device) according to an attribute of the external electronic device. The applications 370 may include an application received from the external electronic device. The applications 370 may include a preloaded application or a third-party application downloadable from a server. The names of the elements of the program module 310 may vary with the type of an OS.

At least a part of the program module 310 may be implemented with software, firmware, hardware, or a combination thereof. At least a part of the program module 310 may be implemented (e.g., executed) by the processor 120. At least a part of the program module 310 may include a module, a program, a routine, sets of instructions, or a process for performing at least one function.

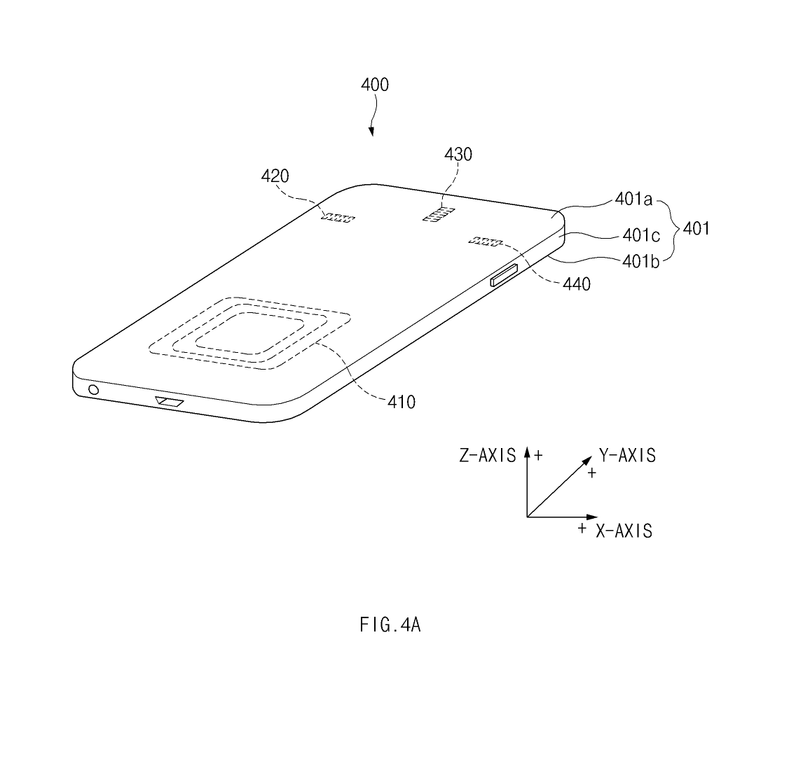

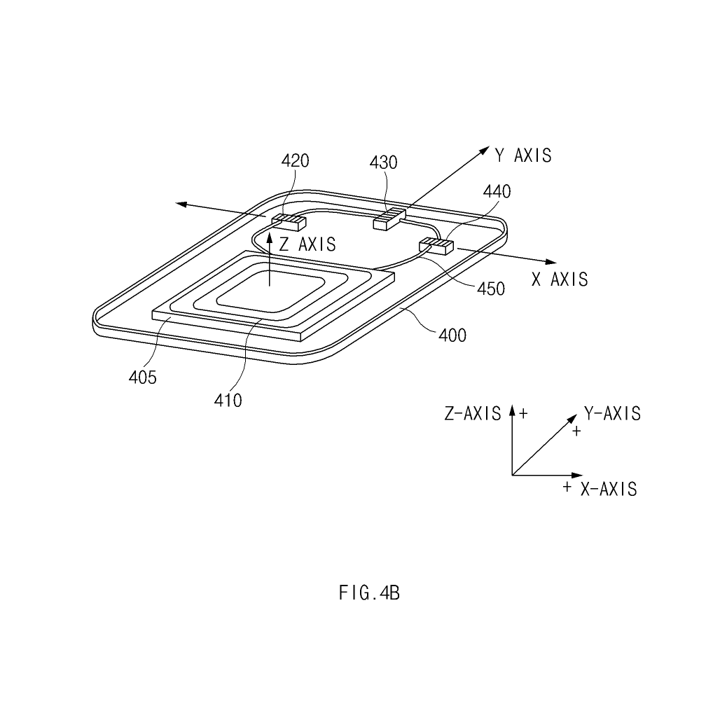

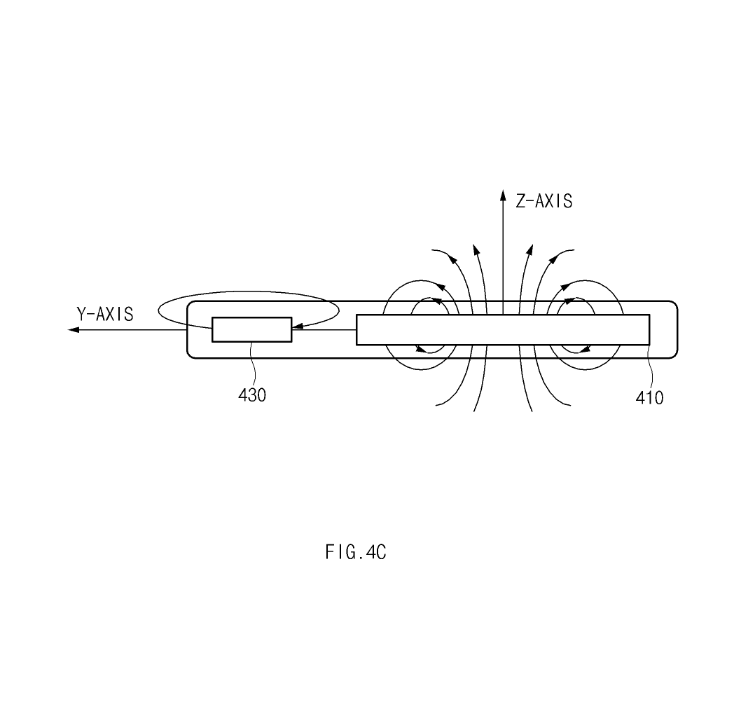

FIG. 4A is illustrates the outside of an electronic device including a plurality of conductive patterns, according to an embodiment of the present disclosure.

Referring to FIG. 4A, an electronic device 400 is provided. An exterior of the electronic device 400 may be surrounded by a housing 401. The housing 401 may fix and protect various parts (e.g., a processor, a communication circuit, a display panel, a touch panel, a battery, etc.) mounted therein. The housing 401 includes a first plate 401a, a second plate 401b, and at least one side part 401c.

The first plate 401a may be disposed to face a first direction (e.g., a positive direction of z-axis), and the second plate 401b may be disposed to face a second direction (e.g., a negative direction of z-axis) opposite to the first direction. The first plate 401a may be at least a part of a rear cover or a battery cover of the electronic device 400. The second plate 401b may be at least a part of a surface (or a front surface) on which a main display of the electronic device 400 is mounted.

At least parts of the first plate 401a and the second plate 401b may be disposed to be parallel with each other and may be disposed to maintain a specified distance or more. A space in which various parts (e.g., a processor, a communication module, a printed circuit board (PCB), a battery, etc.) are mounted may be defined between the first plate 401a and the second plate 401b.

The side part 401c may surround at least a part of the space between the first plate 401a and the second plate 401b. The side part 401c may be disposed to face a third direction (e.g., at least one direction of an XY plane) different from the first direction and the second direction. The side part 401c may extend from the second plate 401b (e.g., an edge display). Alternatively, the side part 401c may be formed to be separate from the second plate 401b.

The housing 401 includes a first conductive pattern 410, a second conductive pattern, 420, a third conductive pattern 430, and a fourth conductive pattern 440. The first conductive pattern 410 to the fourth conductive pattern 440 may output electromagnetic waves to be radiated in an external direction of the electronic device 400. For example, the first conductive pattern 410 may mainly output electromagnetic waves in the first direction of the electronic device 400. The second to fourth conductive patterns 420 to 440 may mainly output electromagnetic waves in the third direction of the electronic device 400.

The arrangement of the first conductive pattern 410 to the fourth conductive pattern 440 is not limited to the arrangement illustrated in FIG. 4A. FIGS. 4B and 4C illustrate the inside of the electronic device including a plurality of conductive patterns, according to an embodiment of the present disclosure.

Referring to FIGS. 4B and 4C, the electronic device 400 includes the first conductive pattern 410, the second conductive pattern 420, the third conductive pattern 430, and the fourth conductive pattern 440.

The first conductive pattern 410 to the fourth conductive pattern 440 may form a radiator for short range communication such as NFC, MST, etc.

The first conductive pattern 410 is a loop-type (or coil-type) pattern and may transmit electromagnetic waves (or a short range communication signal) in a normal direction of a closed surface defined by a loop, for example, in a positive direction of z-axis.

In FIG. 4B, the first conductive pattern 410 is illustrated as being mounted on a printed circuit board (PCB) 405. However, the location at which the first conductive pattern 410 is mounted is not limited thereto. For example, the first conductive pattern 410 may be mounted on a flexible printed circuit board (FPCB) or may be mounted on or inside a configuration of a battery of the electronic device 400.

The second conductive pattern 420 to the fourth conductive pattern 440, each of which is a chip IC, may have a shape in which a coil is wound in a cylindrical shape. The second conductive pattern 420 to the fourth conductive pattern 440 may transmit electromagnetic waves (or short range electromagnetic waves) in a normal direction of a closed surface based on the shape of the wound coil. For example, the second conductive pattern 420 may transmit electromagnetic waves in a negative direction of X-axis, the third conductive pattern 430 may transmit electromagnetic waves in a positive direction of Y-axis, and the fourth conductive pattern 440 may transmit electromagnetic waves in a positive direction of X-axis. For example, the second conductive pattern 420 and the fourth conductive pattern 440 may transmit electromagnetic waves in opposite directions.

The electronic device 400 may transmit electromagnetic waves (or short range communication signals) in a plurality of directions by using a plurality of conductive patterns (e.g., the first conductive pattern 410 to the fourth conductive pattern 440). For example, communication may be possible when a user allows a rear surface (a positive direction of Z-axis) to approach an NFC reader. Alternatively, communication may be possible when the user allows a left or right side surface (a positive direction or a negative direction of X-axis) or a top surface (a positive direction of Y-axis) of the electronic device 400 to approach the NFC reader. The user may allow the electronic device 400 to contact an external electronic device, such as an NFC reader or an MST reader, in various directions, thereby performing short range communication.

The electromagnetic waves (or short range communication signals) may be transmitted to the outside of the electronic device 400 through a non-conductor. For example, electromagnetic waves transmitted from each of the first conductive pattern 410 to the fourth conductive pattern 440 may be output through a non-conductor (e.g., not a metal material, but a plastic injection-molding area of the housing 401 of the electronic device 400).

The first conductive pattern 410 may be connected with the second conductive pattern 420 to the fourth conductive pattern 440 through a conductive line 450 to operate. The first conductive pattern 410 to the fourth conductive pattern 440 may be connected with a communication circuit and may work under the control of the communication circuit.

The communication circuit may be connected with the first conductive pattern 410 and may be separately connected with the second conductive pattern 420 to the fourth conductive pattern 440. In this case, the communication circuit may use the first conductive pattern 410 as an NFC antenna operating in a read/write mode and may use the second conductive pattern 420 to the fourth conductive pattern 440 as an NFC antenna operating in a card mode.

The first conductive pattern 410 to the fourth conductive pattern 440 may be connected with different communication circuits. For example, the electronic device 400 may include two communication circuits (e.g., a first communication circuit and a second communication circuit). The first communication circuit may be connected with the first conductive pattern 410, and the second communication circuit may be connected with the second conductive pattern 420 to the fourth conductive pattern 440.

The electronic device 400 may include a memory, and the memory may store an instruction that is executable in the communication circuit. For example, the communication circuit may acquire an instruction for using the first conductive pattern 410 in the read/write mode from the memory and may acquire an instruction for using the second conductive pattern 420 to the fourth conductive pattern 440 in the card mode from the memory.

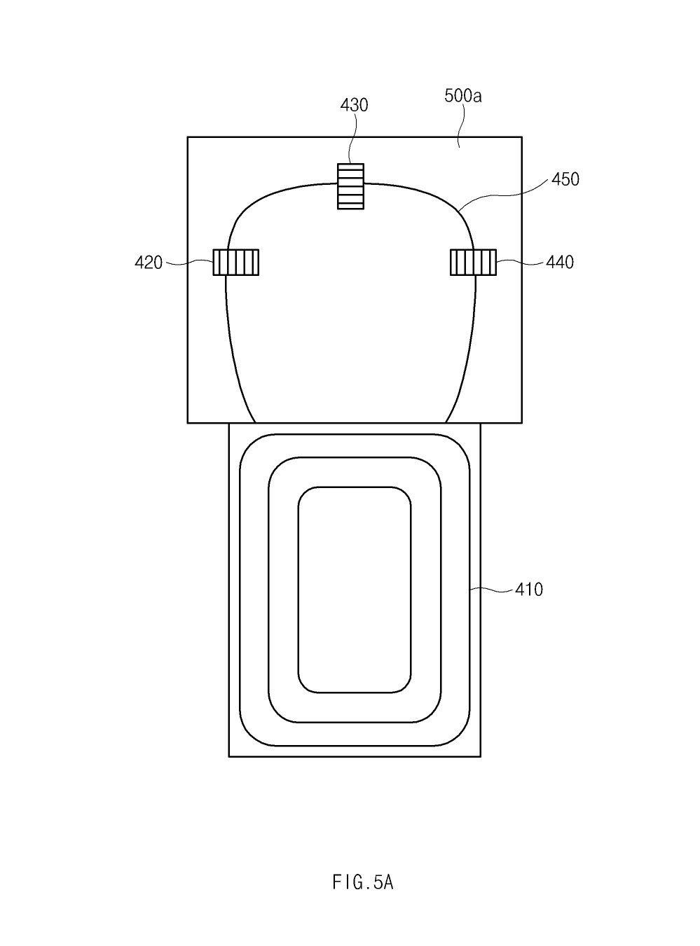

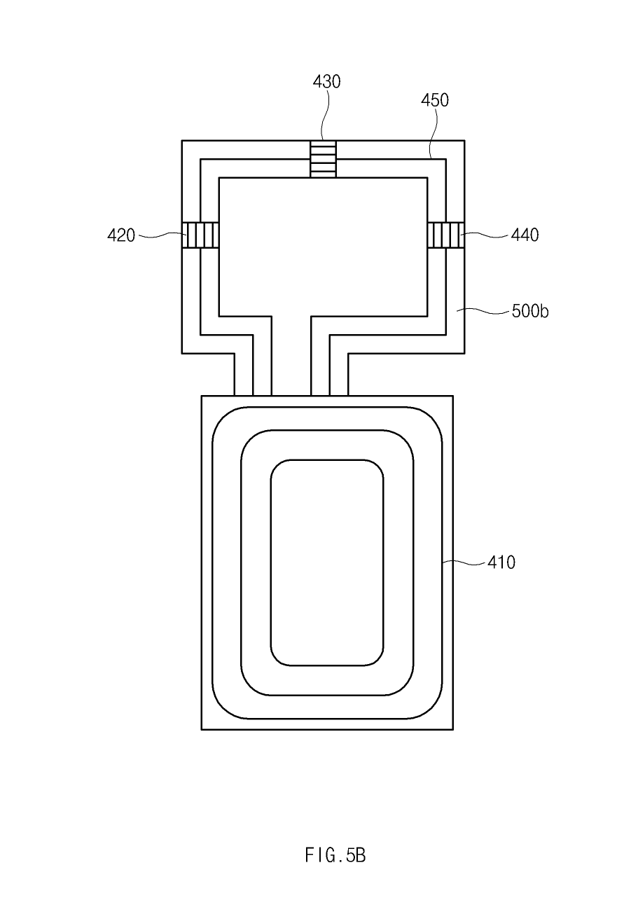

FIGS. 5A and 5B illustrate a plurality of conductive patterns mounted in an electronic device, according to an embodiment of the present disclosure.

Referring to FIG. 5A, the second conductive pattern 420 to the fourth conductive pattern 440 may be mounted on a PCB 500a connected with the first conductive pattern 410. In this case, the second conductive pattern 420 to the fourth conductive pattern 440 may be connected with the first conductive pattern 410 through the conductive line 450.

Referring to FIG. 5B, the second conductive pattern 420 to the fourth conductive pattern 440 may be mounted on a FPCB 500b connected with the first conductive pattern 410. In this case, the second conductive pattern 420 to the fourth conductive pattern 440 may be connected with the first conductive pattern 410 through the conductive line 450.

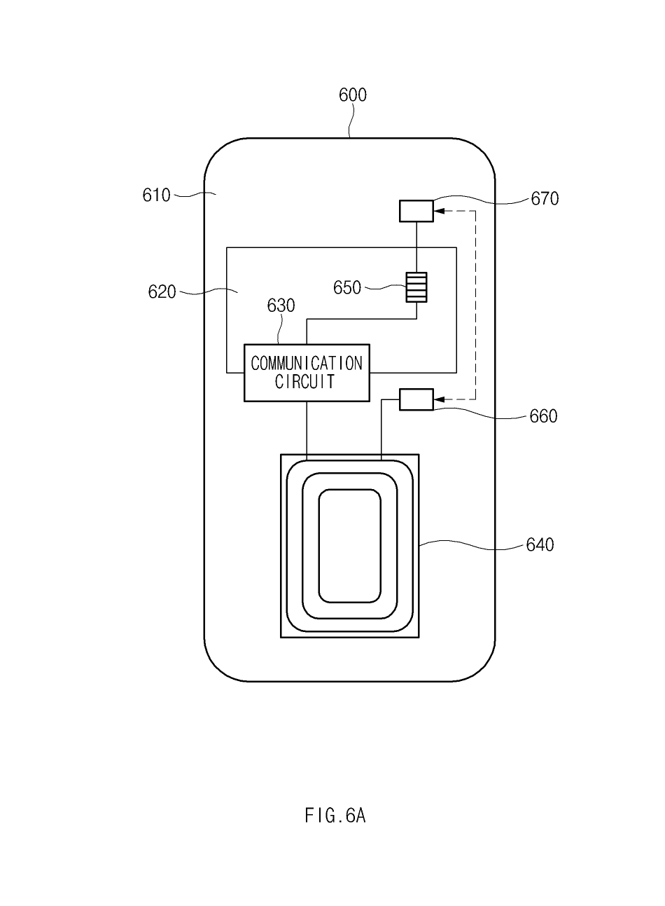

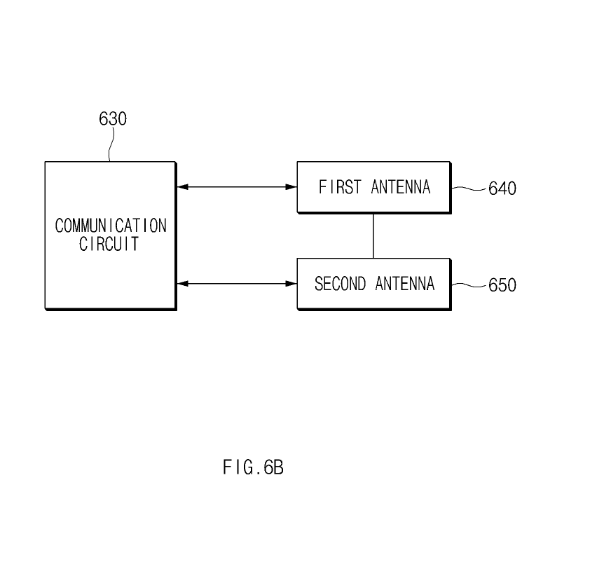

FIG. 6A illustrates a configuration of a plurality of conductive patterns that perform short range communication in an electronic device, according to an embodiment of the present disclosure.

Referring to FIG. 6A, an electronic device 600 is provided. The electronic device 600 includes a communication circuit 630, a first conductive pattern 640, a second conductive pattern 650, a first contact member 660, and a second contact member 670. The communication circuit 630, the first conductive pattern 640, and the second conductive pattern 650 may be mounted on a printed circuit board of the electronic device 600. Also, a first area 610 of the electronic device 600 may be formed of a conductor (e.g., a metal housing). Also, a second area 620 of the electronic device 600 may be formed of a non-conductor (e.g., a plastic injection-molding area). The printed circuit board includes a first contact member 660 and a second contact member 670 that are used for a contact with the first area 610.

Electromagnetic waves transmitted from the first conductive pattern 640 and the second conductive pattern 650 may not pass through the first area 610 and may pass through the second area 620. The first conductive pattern 640 may be mounted under an injection-molding area.

The communication circuit 630 may provide a control signal to the first conductive pattern 640 to operate the first conductive pattern 640 and the second conductive pattern 650. The control signal may be transferred to the first contact member 660 through the first conductive pattern 640. The control signal may be transferred from the first contact member 660 to the second contact member 670 through the first area 610, for example, through the path indicated by the dotted line in FIG. 6A. The control signal may be provided from the second contact member 670 to the second conductive pattern 650, and the control signal may be returned to the communication circuit 630. The first conductive pattern 640 and the second conductive pattern 650 may transmit electromagnetic waves to the outside through the control signal.

FIG. 6B is a block diagram of a communication circuit and a plurality of conductive patterns in an electronic device, according to an embodiment of the present disclosure

Referring to FIG. 6B the communication circuit 630, the first conductive pattern 640, and the second conductive pattern 650 of the electronic device 600 are shown in a simplified manner. The first conductive pattern 640 and the second conductive pattern 650 may be interconnected, and the communication circuit 630 may operate the first conductive pattern 640 and the second conductive pattern 650 together.

Alternatively, the first conductive pattern 640 and the second conductive pattern 650 may not be interconnected. In this case, the communication circuit 630 may provide the first conductive pattern 640 with a control signal for operating the first conductive pattern 640 and may separately provide the second conductive pattern 650 with a control signal for operating the second conductive pattern 650.

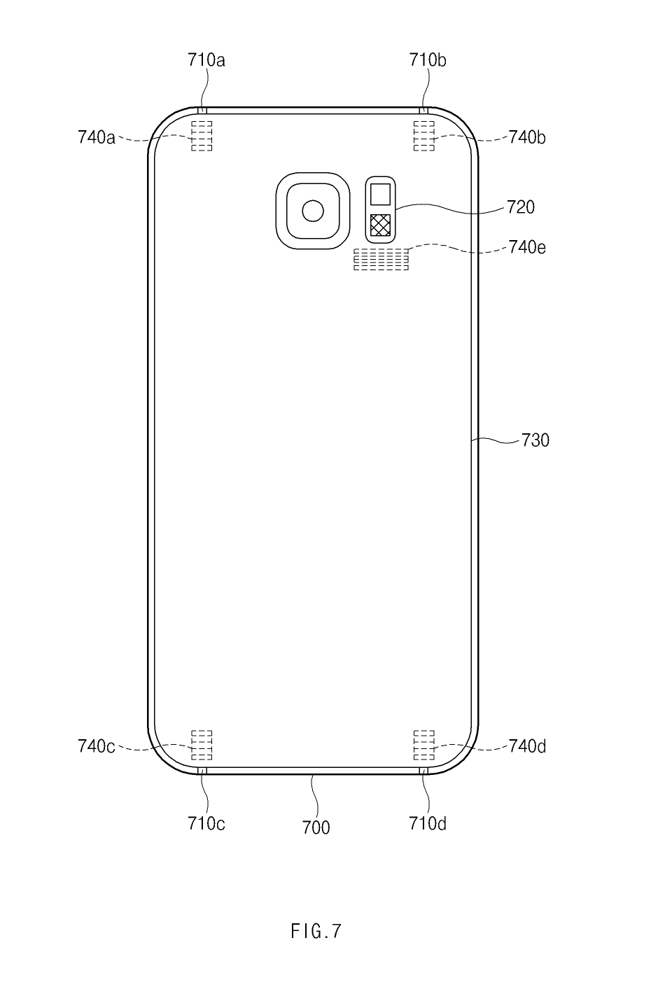

FIG. 7 illustrates a configuration of a plurality of conductive patterns that perform short range communication in an electronic device, according to an embodiment of the present disclosure.

Referring to FIG. 7, an electronic device 700 is provided. The electronic device includes a metal housing, which includes a plurality of non-conductive slits, such as a first slit 710a, a second slit 710b, a third slit 710c, and a fourth slit 710d, a non-conductive hole 720, and a plurality of conductive patterns, such as a first conductive pattern 740a, a second conductive pattern 740b, a third conductive pattern 740c, a fourth conductive pattern 740d, and a fifth conductive pattern 740e.

The first conductive pattern 740a to the fourth conductive pattern 740d may be disposed adjacent to the first slit 710a to the fourth slit 710d, respectively. Each of the first conductive pattern 740a to the fourth conductive pattern 740d may be a chip IC in which a coil is wound in a vertical direction. The first conductive pattern 740a to the fourth conductive pattern 740d may transmit electromagnetic waves through the first slit 710a to the fourth slit 710d, respectively.

The hole 720 may be used to expose an image sensor (e.g., a camera), a flash, etc. to the outside of the electronic device 700, and the image sensor, the flash, etc. may be supported by a non-conductive member. At least a part of the non-conductive member may be exposed in the hole 720, and the fifth conductive pattern 740e may transmit electromagnetic waves through the exposed part of the non-conductive member.

In the case where the image sensor, the flash, etc. is supported by a metal member, if a gap exists between the metal member and the hole 720, the fifth conductive pattern 740e may transmit electromagnetic waves through the gap.

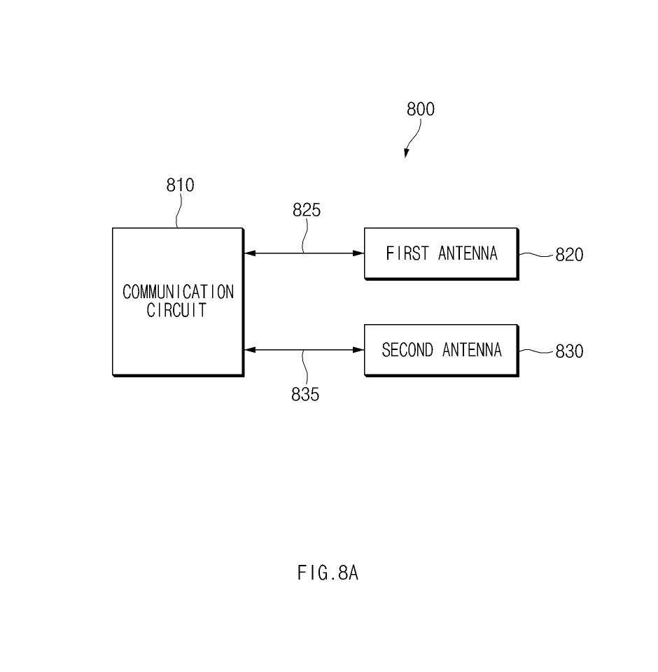

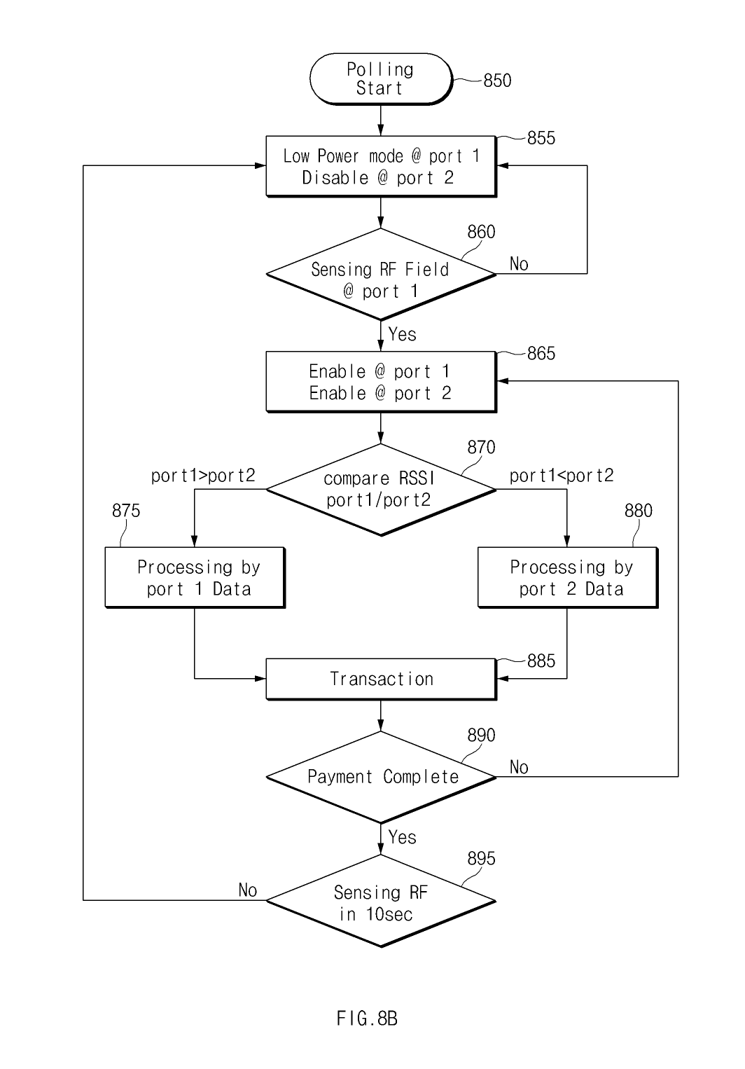

FIG. 8A is a block diagram of a communication circuit and a plurality of conductive patterns in an electronic device, according to an embodiment of the present disclosure.

Referring to FIG. 8A, a communication circuit 810, a first conductive pattern 820, and a second conductive pattern 830 of an electronic device 800 are shown. Unlike the configuration shown in FIG. 6A, in FIG. 8A, the first conductive pattern 820 and the second conductive pattern 830 may be connected with the communication circuit 810 through a first path 825 and a second path 835, while the first conductive pattern 820 and the second conductive pattern 830 are not interconnected.

The first path 825 and/or the second path 835 may include two paths for a differential signal. For example, the communication circuit 810 may include four ports. In this case, two of the four ports may be connected with two ports of the first conductive pattern 820, and the remaining two ports may be connected with two ports of the second conductive pattern 830.

To transmit a short range signal through the first conductive pattern 820, the communication circuit 810 may use only one path or may use both paths. The communication circuit 810 may operate at low power when only one path is used, compared with when two paths are used. For example, since the intensity of a signal becomes larger as power consumption become larger, the intensity of a signal transmitted when two paths are used may be larger than the intensity of a signal transmitted when only one path is used.

FIG. 8B is a flowchart of a method for performing communication by using a differential signal in an electronic device, according to an embodiment of the present disclosure.

Referring to FIG. 8B, a method of transmitting a signal by using a differential signal in the electronic device 800 is described.

In step 850, the electronic device 800 may perform a polling operation by using short range communication (e.g., NFC or MST). For example, the polling operation may be for a transaction with a POS device.

In step 855, the electronic device 800 operates a conductive pattern at low power by using only a first port, without using a second port.

In step 860, the electronic device 800 determines whether a radio frequency (RF) field is sensed through the conductive pattern by using only the first port. The RF field may correspond to the short range communication.

If the RF field is not sensed, the electronic device 800 returns to step 855 to continue to operate the conductive pattern by using only the first port.

If the RF field is sensed, the electronic device 800 proceeds to step 865 to activate both the first port and the second port.

In step 870, the electronic device 800 compares a received signal strength indication (RSSI) value of the first port and an RSSI value of the second port.

If the RSSI value of the first port is larger than the RSSI value of the second port, then in step 875, the electronic device 800 determines that the first port is used for the short range communication.

If the RSSI value of the second port is larger than the RSSI value of the first port, then in step 880, the electronic device 800 determines that the second port is used for the short range communication.

In step 885, the electronic device 800 performs the transaction through the short range communication by using the first port or the second port, based on the determination of step 875 or step 880.

In step 890, the electronic device 800 determines whether the transaction is completed.

If it is determined that the transaction is not completed, the electronic device 800 returns to step 865, and activates the first port and the second port.

If it is determined that the transaction is completed, the electronic device 800 proceeds to step 895 to again sense an RF signal.

If the RF signal is not sensed during a specified time period (e.g., 10 seconds), the electronic device 800 returns to step 855 and again operates at low power.

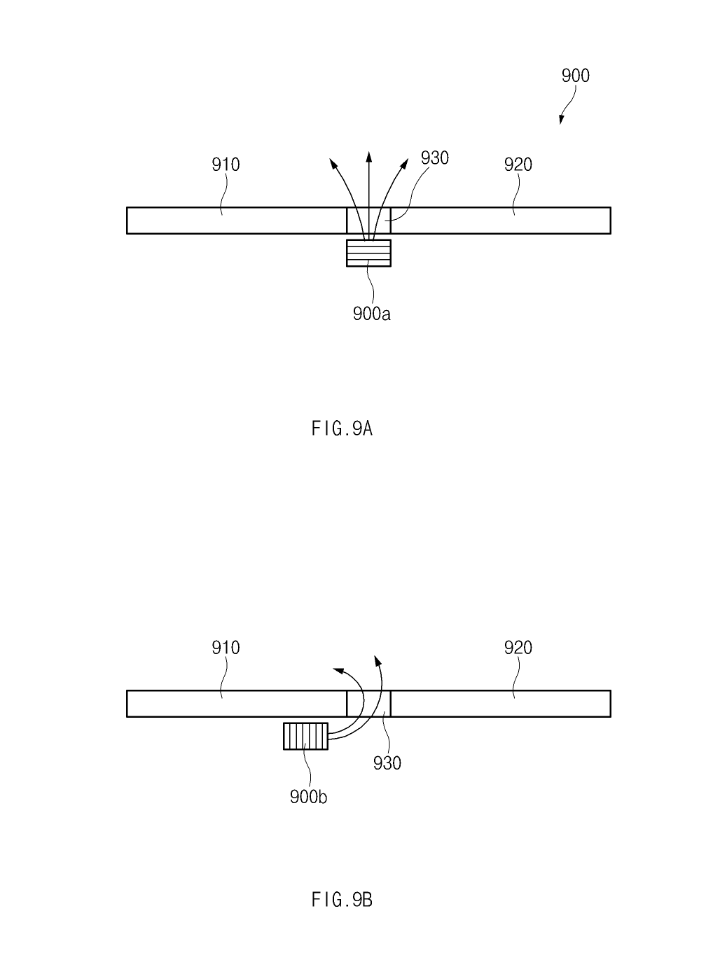

FIGS. 9A and 9B illustrate an electromagnetic wave transmission path that is based on a wound direction of a coil and a location of a non-conductor, according to an embodiment of the present disclosure.

Referring to FIG. 9A, a non-conductor 930 may be disposed between a first metal member 910 and a second metal member 920, and a conductive pattern 900a (e.g., a chip IC) may be located under the non-conductor 930 of an electronic device 900.

The first metal member 910 and the second metal member 920 may constitute a part of a metal housing of the electronic device 900, and the non-conductor 930 may be a slit located in the metal housing.

The conductive pattern 900a may transmit electromagnetic waves through the non-conductor 930 in a normal direction (as shown by the arrow directions illustrated in FIG. 9A) of a closed surface defined by a coil.

Referring to FIG. 9B, when the conductive pattern 900b is spaced apart from the non-conductor 930 by a predetermined distance, a conductive pattern 900b may transmit, through the non-conductor 930, an electromagnetic wave of a direction, which becomes more distant from a normal direction and is spread in a direction different from the normal direction.

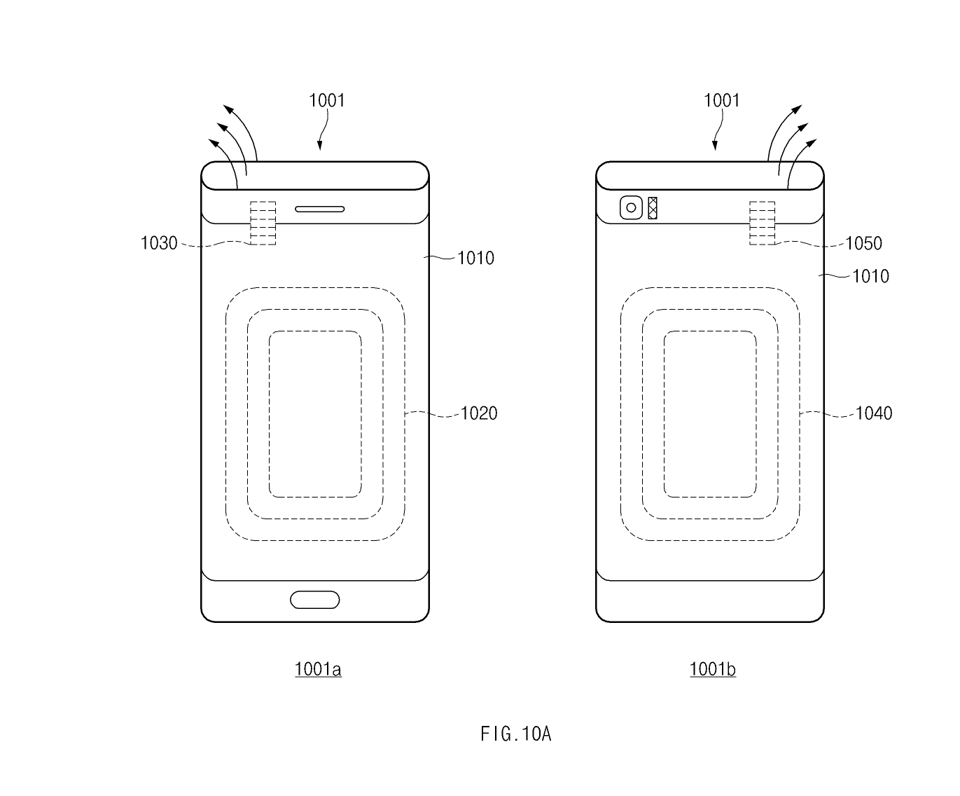

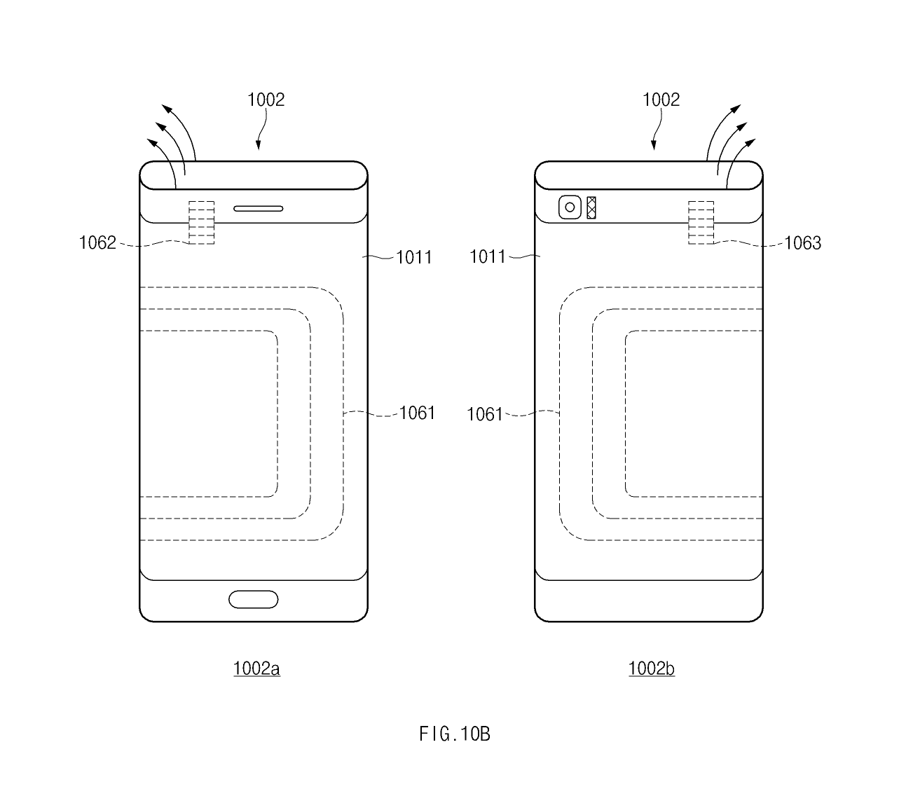

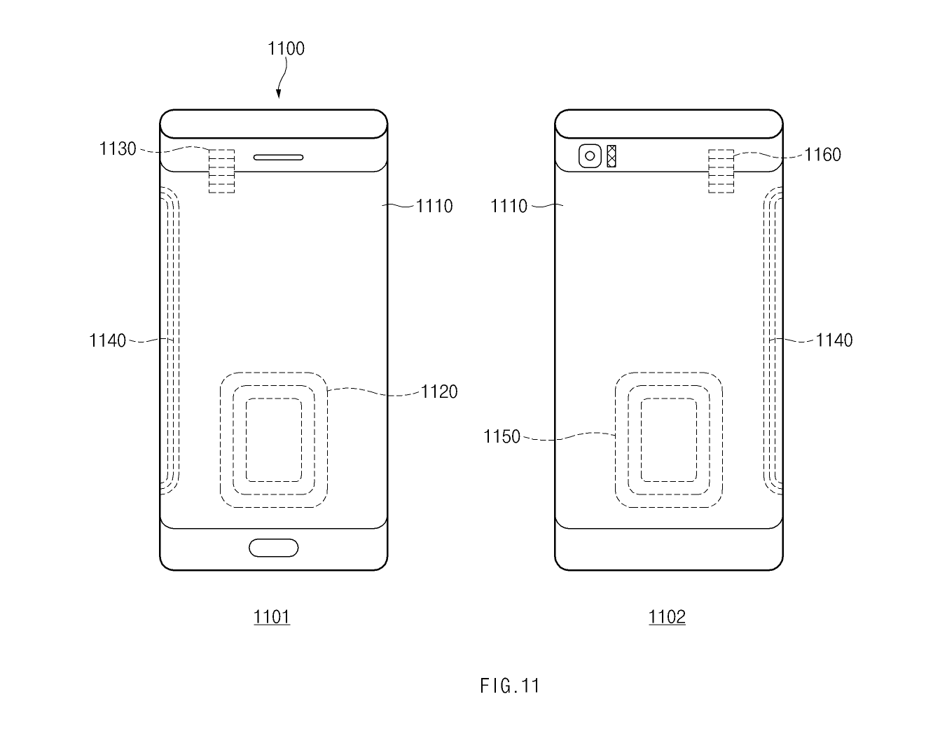

FIGS. 10A and 10B illustrate a configuration of a plurality of conductive patterns in an electronic device having a display covering multiple surfaces, according to an embodiment of the present disclosure.

Referring to FIG. 10A, an electronic device 1001 is provided. The electronic device 1001 includes a display 1010 that covers a first surface area 1001a (e.g., a front surface) and a second surface area 1001b (e.g., a rear surface) of the electronic device 1001. For example, the display 1010 may surround the area of the electronic device 1001 other than the upper and lower side surfaces. The electronic device 1001 includes a first conductive pattern 1020 and a second conductive pattern 1030 in the first surface area 1001a. The first conductive pattern 1020 may be a conductive pattern of a loop shape, and the second conductive pattern 1030 may be a conductive pattern of a chip IC shape. The first conductive pattern 1020 may be disposed in the interior of the electronic device 1001 which is under a display 1010, for example, the first conductive pattern 1020 may be attached on an inner surface of a panel constituting the display 1010.

The electronic device 1001 includes a third conductive pattern 1040 and a fourth conductive pattern 1050 in the second surface area 1001b. The third conductive pattern 1040 may be closely disposed on an inner surface of the display 1010.

The first conductive pattern 1020 and the third conductive pattern 1040 may transmit electromagnetic waves to the first surface and the second surface, respectively, of the electronic device 1001, through the display 1010. Each of the second conductive pattern 1030 and the fourth conductive pattern 1050 may transmit electromagnetic waves in a direction of an upper end of the electronic device 1001.

Referring to FIG. 10B, an electronic device 1002 is provided. The electronic device 1002 includes a display 1011 that covers a first surface area 1002a (e.g., a front surface) and a second surface area 1002b (e.g., a rear surface) of the electronic device 1002.

The electronic device 1002 includes a first conductive pattern 1061 disposed in both the first surface area 1002a and the second surface area 1002b. A part of the first conductive pattern 1061 may be disposed in the first surface area 1002a, and the remaining part of the first conductive pattern 1061 may be disposed in the second surface area 1002b. The first conductive pattern 1061 may be of a loop shape.

In FIG. 10B, the first conductive pattern 1061 is illustrated as being connected through a left surface of the electronic device 1002. However, the connection of the conductive pattern 1061 is not limited thereto. For example, the first conductive pattern 1061 may be connected through a right surface of the electronic device 1002. The electronic device 1002 may be implemented such that electromagnetic waves are transmitted through a side connection part connecting a first surface portion and a second surface portion of the first conductive pattern 1061. In this case, electromagnetic waves may be also transmitted through the side connection part, and thus, NFC communication or MST communication may be performed.

The electronic device 1002 includes a second conductive pattern 1062 in the first surface area 1002a. The second conductive pattern 1062 may be of a chip IC shape.

The electronic device 1002 includes a third conductive pattern 1063 in the second surface area 1002b. The third conductive pattern 1063 may be of a chip IC shape.

The electronic device 1002 may transmit electromagnetic waves into an upper end of the electronic device 1002 by using the second conductive pattern 1062 or the third conductive pattern 1063.

FIG. 11 illustrates a configuration of a plurality of conductive patterns in an electronic device having a display covering multiple surfaces, according to an embodiment of the present disclosure.

Referring to FIG. 11, an electronic device 1100 is provided. In the electronic device 1100, a display 1011 may cover a first surface area 1101 (e.g., a front surface) and a second surface area 1102 (e.g., a rear surface) of the electronic device 1100. For example, the electronic device 1100 includes a display 1110 that surrounds the surfaces of the electronic device 1100 other than the upper and lower side surfaces. A first conductive pattern 1120 and a second conductive pattern 1130 may be included in the first surface area 1101, and a third conductive pattern 1150 and a fourth conductive pattern 1160 may be included in the second surface area 1102.

The electronic device 1100 includes a fifth conductive pattern 1140 on the first surface area 1101, the second surface area 1102, and another side surface.

The first conductive pattern 1120 and the third conductive pattern 1150 may transmit electromagnetic waves to the first surface area 1101 and the second surface area 1102, respectively, of the electronic device 1100, through the display 1110. Also, both the second conductive pattern 1130 and the fourth conductive pattern 1160 may transmit electromagnetic waves in a direction of an upper end of the electronic device 1100. Alternatively, the fifth conductive pattern 1140 may transmit electromagnetic waves into a side surface of the electronic device 1100.

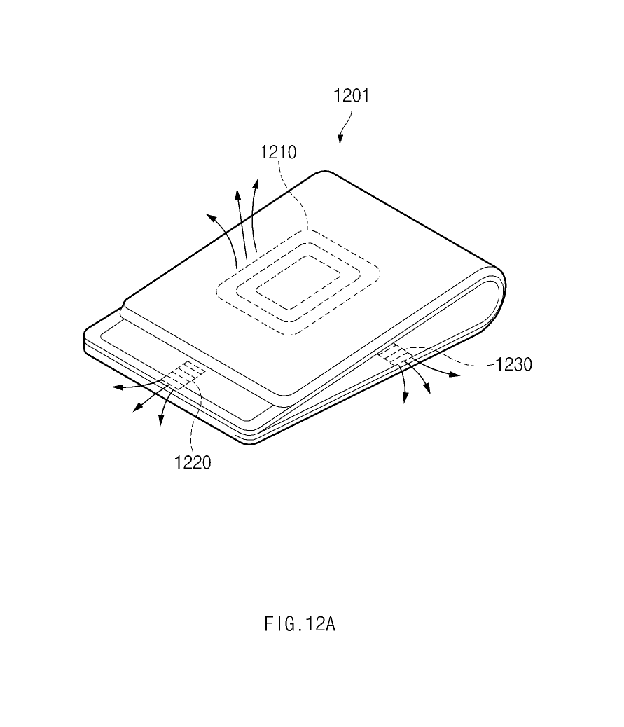

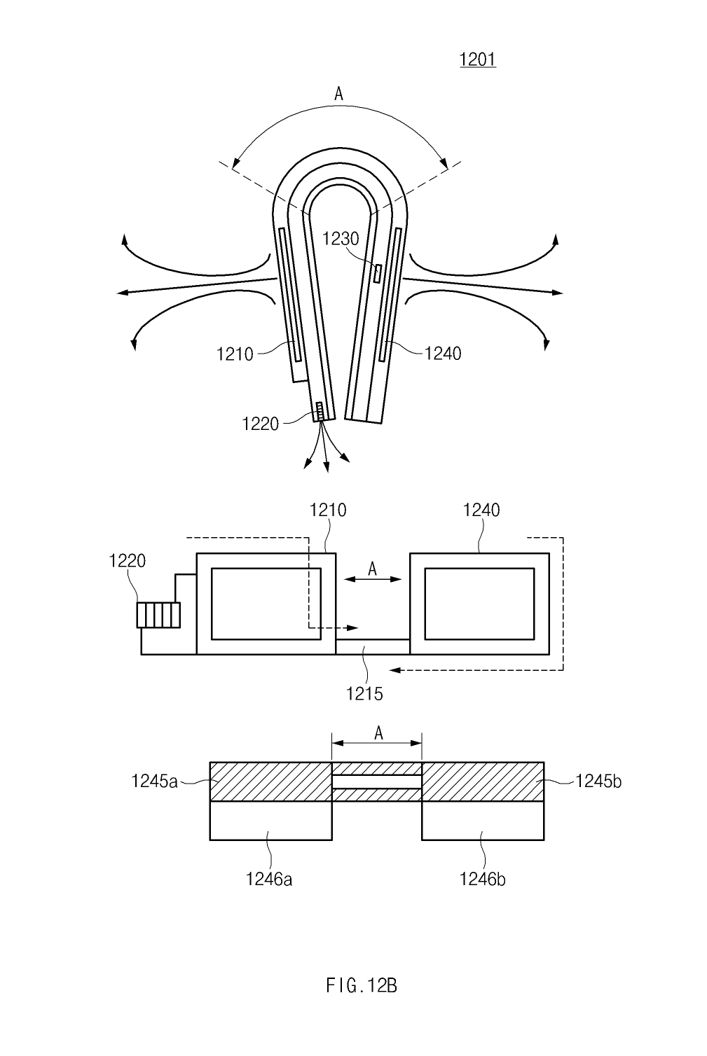

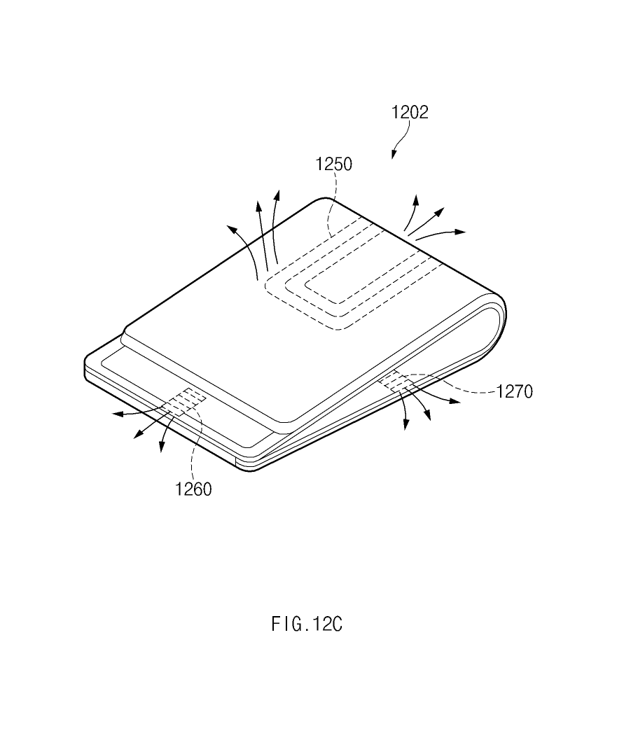

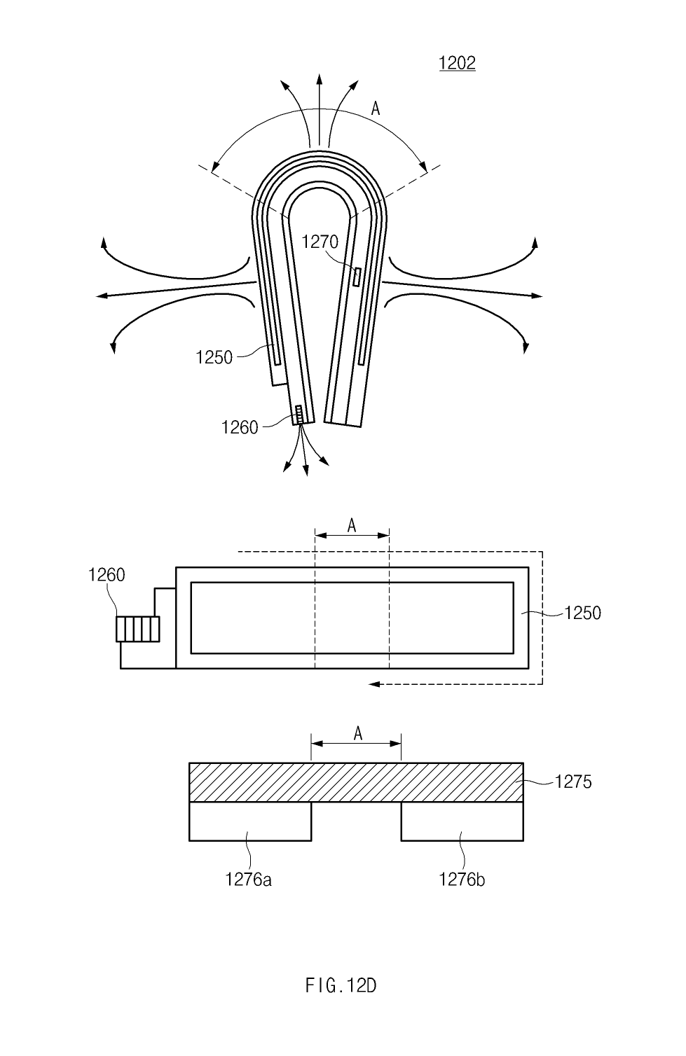

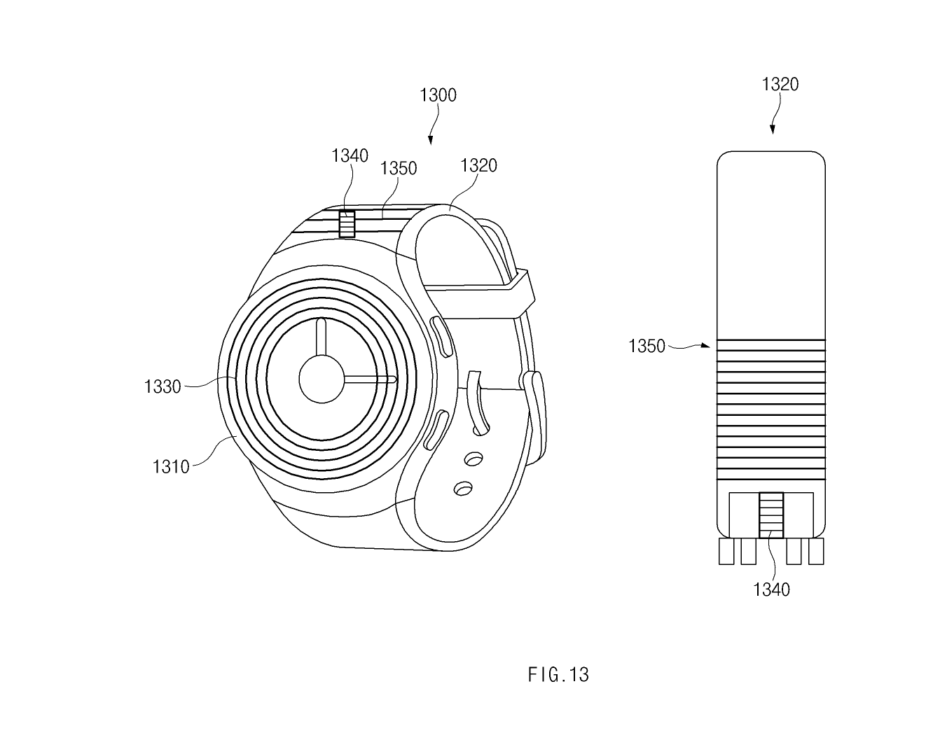

FIGS. 12A to 12D illustrate a configuration of a plurality of conductive patterns in an electronic device having a flexible display, according to an embodiment of the present disclosure.

Referring to FIGS. 12A and 12B, an electronic device 1201 is provided. The electronic device 1201 includes a flexible display so as to be folded. The electronic device 1201 includes a first conductive pattern 1210 that transmits electromagnetic waves from a first surface (a surface which is exposed to the outside through a folding operation) to an outer direction and a second conductive pattern 1220 and a third conductive pattern 1230 that transmit electromagnetic waves in a side direction.

The electronic device 1201 may further include a fourth conductive pattern 1240 that transmits electromagnetic waves from another area of a first surface to an outer direction, as shown in FIG. 12B.

The electronic device 1201 may further include another conductive pattern that transmits electromagnetic waves from a second surface (a surface which is folded inwardly through a folding operation) to an outer direction.

The first conductive pattern 1210 and the fourth conductive pattern 1240 may transmit electromagnetic waves from the first surface (a surface which is exposed to the outside through a folding operation) of the electronic device 1201 to an outer direction.

The electronic device 1201 includes a conductive line 1215 that connects the first conductive pattern 1210 and the fourth conductive pattern 1240, as shown in FIG. 12B. The conductive line 1215 may be disposed in a folding area (section A) in which the electronic device 1201 is folded. The first conductive pattern 1210 and the fourth conductive pattern 1240 may be connected through the conductive line 1215 and may simultaneously operate in response to one control signal generated by a communication circuit.

The first conductive pattern 1210 may be disposed in a first FPCB 1245a, and the fourth conductive pattern 1240 may be disposed in a second FPCB 1245b. The first conductive pattern 1210 and the fourth conductive pattern 1240 may be connected through the conductive line 1215. The first FPCB 1245a and the second FPCB 1245b in which the first conductive pattern 1210 and the fourth conductive pattern 1240 are respectively disposed, may be covered by a first ferrite sheet 1246a and a second ferrite sheet 1246b, respectively.

Referring to FIGS. 12C and 12D, an electronic device 1202 is provided. The electronic device 1202 includes a flexible display so as to be folded. The electronic device 1202 includes a first conductive pattern 1250 that transmits electromagnetic waves from a first surface (a surface which is exposed to the outside through a folding operation) to an outer direction, a second conductive pattern 1260, and a third conductive pattern 1270 that transmit electromagnetic waves in a side direction.

Unlike the electronic device 1201 shown in FIGS. 12A and 12B, in FIGS. 12C and 12D, the first conductive pattern 1250 may be disposed on the entire first surface (a surface which is exposed to the outside through a folding operation) and may transmit electromagnetic waves to an outer direction. As such, the first conductive pattern 1250 may transmit electromagnetic waves to the outside in a folding area (section A) and may perform wireless communication.

The first conductive pattern 1250 may be disposed in one FPCB 1275. At least a part of the FPCB 1275 in which the first conductive pattern 1250 is disposed may be covered by a ferrite sheet. In various embodiments, the area other than the folding area (section A) may be covered by a first ferrite sheet 1276a and a second ferrite sheet 1276b.

FIG. 13 illustrates a configuration of a plurality of conductive patterns in a wearable electronic device, according to an embodiment of the present disclosure.

Referring to FIG. 13, a wearable electronic device 1300 is provided. The electronic device 1300 is illustrated as being a smart watch. However, embodiments of the present disclosure may not be limited thereto. The electronic device 1300 includes a body 1310 and a strap 1320.

The body 1310 of the electronic device 1300 includes a first conductive pattern 1330. The first conductive pattern 1330 may transmit electromagnetic waves into a first surface (e.g., a surface on which a display is disposed) of the electronic device 1300.

The strap 1320 of the electronic device 1320 includes a second conductive pattern 1340 and a third conductive pattern 1350. When a user wears the electronic device 1300, the second conductive pattern 1340, which is a chip IC, may transmit electromagnetic waves in a direction (e.g., a side direction, a direction perpendicular to a front direction of the first conductive pattern 1330, a direction perpendicular to a surface on which that the strap 1320 faces the outside, etc.) of a second surface different from a first surface of the electronic device 1300. The third conductive pattern 1350 may be formed to surround the strap 1320. When the user wears the electronic device 1300 on his/her wrist, the third conductive pattern 1350 may transmit electromagnetic waves in a direction (e.g., toward a wrist of a user, a direction of his/her palm, a direction of a surface opposite to a surface on which a display is disposed, etc.) of a third surface of the electronic device 1300.

In FIG. 13, the second conductive pattern 1340 is illustrated as being disposed in the strap 1320. However, location of the second conductive pattern 1340 is not limited thereto. For example, the electronic device 1300 may include both the first conductive pattern 1330 and the second conductive pattern 1340. The first conductive pattern 1330 may be disposed to transmit electromagnetic waves into the first surface (e.g., a front surface being a surface on which a display is disposed) of the electronic device 1300, and the second conductive pattern 1340 may be disposed to transmit electromagnetic waves to a second surface (e.g., a rear surface being a surface on which a cover is disposed or a side surface (a surface on which a button is disposed)) of the electronic device 1300. When the user wears the electronic device 1300, as a chip IC, the second conductive pattern 1340 may transmit electromagnetic waves in a direction (e.g., a direction of a side surface, a direction of a rear surface, etc.) of a second surface different from the first surface (e.g., the front surface) of the electronic device 1300.

According to various embodiments of the present disclosure, an electronic device includes a housing including a first plate facing a first direction, a second plate facing a second direction opposite to the first direction, and at least one side part surrounding at least one part of a space between the first plate and the second plate and facing a third direction different from the first direction and the second direction, a first conductive pattern including a first coil having a first axis substantially extending in the first direction or the second direction, a second conductive pattern including a second coil having a second axis substantially extending in the third direction, and a communication circuit electrically connected with the first conductive pattern and the second conductive pattern.

The first conductive pattern and the second conductive pattern are disposed inside the housing.

The at least one side part is formed to extend from the second plate or to be separate from the second plate.

The first coil is formed on a surface substantially parallel with the first plate and/or the second plate.

The second coil is formed in a cylindrical shape extending in the third direction.

The first coil has a first diameter, and the second coil has a second diameter smaller than the first diameter.

The first coil is formed in a flexible printed circuit board (FPCB), and the second coil is formed as a part of an integrated circuit (IC) chip.

The communication circuit supports at least one of a near field communication (NFC) protocol or a magnetic secure transmission (MST) protocol.

The second conductive pattern radiates electromagnetic waves in an outer direction through at least one open space defined in the housing. The at least one open space includes at least one of a slit defined in the housing and a hole defined in the housing to allow a part of a physical button or sensor to pass through the hole. The at least a portion of the housing is formed of a metal material, and the at least one open space is an insulator in the metal material.

The first conductive pattern is formed in a battery included in the electronic device.

The second conductive pattern includes a plurality of IC chips, and wherein the plurality of IC chips are disposed to face different directions.

According to various embodiments of the present disclosure, an electronic device includes a main display mainly disposed in a first direction, a housing equipped with the main display, a first conductive pattern and a second conductive pattern disposed inside the housing, and a communication circuit configured to transmit and receive wireless electromagnetic waves to and from an outside through the first conductive pattern and the second conductive pattern. The first conductive pattern generates wireless electromagnetic waves in the first direction or a second direction, and the second conductive pattern generates wireless electromagnetic waves in a third direction perpendicular to the first direction.

The first conductive pattern is formed on a surface substantially parallel with the main display. The second conductive pattern is formed in a cylindrical shape extending in the third direction. The first conductive pattern has a first diameter, and the second conductive pattern has a second diameter smaller than the first diameter.

The first conductive pattern is formed in a flexible printed circuit board (FPCB), and wherein the second conductive pattern is formed as a part of an integrated circuit (IC) chip.

The communication circuit supports at least one of a near field communication (NFC) protocol or a magnetic secure transmission (MST) protocol.

The second conductive pattern includes a plurality of IC chips, and the plurality of IC chips are disposed to face different directions.

According to various embodiments of the present disclosure, an electronic device includes a first conductive pattern outputting electromagnetic waves in a first direction, a second conductive pattern outputting electromagnetic waves in a second direction forming a specified angle with the first direction, and a communication circuit electrically connected with the first conductive pattern and the second conductive pattern. The communication circuit performs short range communication with an external device by using at least one of the first conductive pattern and the second conductive pattern.

The first conductive pattern is a loop shape formed in a flexible printed circuit board (FPCB), and the second conductive pattern is formed as a part of an integrated circuit (IC) chip.

A thickness of the first conductive pattern in the first direction is smaller than a thickness of the second conductive pattern in the second direction.

A cross-sectional area of a surface perpendicular to the first direction of the first conductive pattern is larger than a cross-sectional area of a surface perpendicular to the second direction of the second conductive pattern.

At least part of the electronic device (e.g., modules or functions) or methods (e.g., operations) of the present disclosure may be implemented by an instruction stored in a computer-readable storage medium in the form of a program module. When the instruction is executed by a processor, the processor may perform a function corresponding to the instruction. The computer-readable storage medium may be a memory 130.

The computer-readable storage medium may include a hard disk, a floppy disk, a magnetic medium (e.g., a magnetic tape), an optical medium (e.g., a CD-ROM), a DVD, a magneto-optical medium (e.g., a floptical disk), a hardware device (e.g., a read only memory (ROM), a random access memory (RAM), or a flash memory). Further, the instruction may include high-level language codes which may be executed by a computer using an interpreter as well as machine languages created by using a compiler.

A module or a program module of the present disclosure may include at least one of the above-mentioned elements, or some elements may be omitted or other additional elements may be added. Operations performed by the module, the program module, or other elements of the present disclosure may be performed in a sequential, parallel, iterative or heuristic way. Furthermore, some operations may be performed in another order or may be omitted, or other operations may be added.

While the present disclosure has been shown and described with reference to various embodiments, it will be understood by those skilled in the art that various changes in form and details may be made therein without departing from the spirit and scope of the present disclosure, which is defined, not by the detailed description and embodiments, but by the appended claims and their equivalents.

What is claimed is:

1. An electronic device comprising:
a housing having a first plate facing a first direction, a second plate facing a second direction, and at least one side part, between the first plate and the second plate, facing a third direction;
a first conductive pattern comprising a first coil having a first axis substantially extending in the first direction or the second direction;
a second conductive pattern comprising a second coil having a second axis substantially extending in the third direction; and
a communication circuit connected with the first conductive pattern and the second conductive pattern.

2. The electronic device of claim 1, wherein the first conductive pattern and the second conductive pattern are disposed inside the housing.

3. The electronic device of claim 1, wherein the at least one side part is formed to extend from the second plate or to be separate from the second plate.

4. The electronic device of claim 1, wherein the first coil is formed on a surface substantially parallel with at least one of the first plate and the second plate.

5. The electronic device of claim 1, wherein the second coil is formed in a cylindrical shape extending in the third direction.

6. The electronic device of claim 1, wherein the first coil has a first diameter, and
wherein the second coil has a second diameter smaller than the first diameter.

7. The electronic device of claim 1, wherein the first coil is formed in a flexible printed circuit board (FPCB), and
wherein the second coil is formed as a part of an integrated circuit (IC) chip.

8. The electronic device of claim 1, wherein the communication circuit supports at least one of a near field communication (NFC) protocol and a magnetic secure transmission (MST) protocol.

9. The electronic device of claim 1, wherein the second conductive pattern radiates electromagnetic waves in an outer direction through at least one open space defined in the housing.

10. The electronic device of claim 9, wherein the at least one open space includes at least one of a slit for transmitting the electromagnetic waves and a hole exposing a part of a button or a sensor.

11. The electronic device of claim 9, wherein at least a portion of the housing is formed of a metal material, and
wherein the at least one open space is an insulator in the metal material.

12. The electronic device of claim 1, wherein the first conductive pattern is formed in a battery included in the electronic device.

13. The electronic device of claim 1, wherein the second conductive pattern includes a plurality of IC chips, and
wherein the plurality of IC chips are disposed to face different directions.

14. An electronic device comprising:
a main display facing in a first direction;
a housing equipped with the main display;
a first conductive pattern and a second conductive pattern disposed inside the housing; and
a communication circuit configured to transmit and receive wireless electromagnetic waves to and from an outside of the electronic device, through the first conductive pattern and the second conductive pattern,
wherein the first conductive pattern generates wireless electromagnetic waves in the first direction or a second direction, and
wherein the second conductive pattern generates wireless electromagnetic waves in a third direction.

15. The electronic device of claim 14, wherein the first conductive pattern is formed on a surface substantially parallel with the main display.

16. The electronic device of claim 14, wherein the second conductive pattern is formed in a cylindrical shape extending in the third direction, wherein the third direction is perpendicular to the first direction.

17. The electronic device of claim 14, wherein the first conductive pattern has a first diameter, and
wherein the second conductive pattern has a second diameter smaller than the first diameter.

18. The electronic device of claim 14, wherein the first conductive pattern is formed in a flexible printed circuit board (FPCB), and
wherein the second conductive pattern is formed as a part of an IC chip.

19. The electronic device of claim 14, wherein the second conductive pattern includes a plurality of IC chips, and
wherein the plurality of IC chips are disposed to face different directions.

20. An electronic device comprising:
a first conductive pattern outputting electromagnetic waves in a first direction;
a second conductive pattern outputting electromagnetic waves in a second direction forming a specified angle with the first direction; and
a communication circuit connected with the first conductive pattern and the second conductive pattern,
wherein the communication circuit performs short range communication with an external device by using at least one of the first conductive pattern and the second conductive pattern.
